(19) United States
(12) Patent Application Publication
(10) Pub. No.: US 2025/0089454 A1
(43) Pub. Date: Mar. 13, 2025

(54) DISPLAY DEVICE AND METHOD OF MANUFACTURING THE SAME

(71) Applicant: Samsung Display Co., LTD., Yongin-si (KR)

(72) Inventors: Hyun Jun JEONG, Yongin-si (KR); Kwang Soo KO, Yongin-si (KR); Myeong Ho KIM, Yongin-si (KR); Yeon Keon MOON, Yongin-si (KR); Hyun Mo LEE, Yongin-si (KR); Kun Hee JO, Yongin-si (KR)

(73) Assignee: Samsung Display Co., LTD., Yongin-si (KR)

(21) Appl. No.: 18/629,271

(22) Filed: Apr. 8, 2024

(30) Foreign Application Priority Data
Sep. 13, 2023 (KR) 10-2023-0121486

(51) Int. Cl. H10K 59/121; H10K 59/12

(52) U.S. Cl. CPC H10K 59/1213; H10K 59/1201

(57) ABSTRACT

A display device includes a substrate including a display area and a driving circuit area, a first transistor in the display area, and including a first active layer on the substrate and a first gate electrode on the first active layer, a first gate insulating layer between the first active layer and the first gate electrode, and entirely covering the first active layer, a second transistor in the driving circuit area, and including a second active layer on the substrate and a second gate electrode on the second active layer, a second gate insulating layer between the second active layer and the second gate electrode, covering a part of the second active layer overlapping the second gate electrode, and exposing another part of the second active layer, and a first oxide semiconductor layer between the first gate insulating layer and the first gate electrode.

### CROSS-REFERENCE TO RELATED APPLICATION(S)

This application claims priority to and benefits of Korean Patent Application No. 10-2023-0121486 under 35 U.S.C. § 119, filed on Sep. 13, 2023, in the Korean Intellectual Property Office, the entire contents of are incorporated herein by reference.

### BACKGROUND

### 1. Technical Field

Embodiments relate to a display device and a method of manufacturing the display device.

### 2. Description of the Related Art

The importance of display devices has steadily increased with the development of multimedia technology. Accordingly, various types of display devices such as a liquid crystal display device or a light emitting display device have been developed.

### SUMMARY

Aspects of the disclosure provide a display device capable of optimizing operating characteristics of a first transistor disposed in a display area and a second transistor disposed in a driving circuit area and a method of manufacturing the display device.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an aspect of the disclosure, there is provided a display device including a substrate including a display area and a driving circuit area, a first transistor disposed in the display area, and including a first active layer disposed on the substrate and a first gate electrode disposed on the first active layer, a first gate insulating layer disposed between the first active layer and the first gate electrode, and entirely covering the first active layer, a second transistor disposed in the driving circuit area, and including a second active layer disposed on the substrate and a second gate electrode disposed on the second active layer, a second gate insulating layer disposed between the second active layer and the second gate electrode, covering a part of the second active layer overlapping the second gate electrode, and exposing another part of the second active layer, and a first oxide semiconductor layer disposed between the first gate insulating layer and the first gate electrode.

In an embodiment, the display device may further include a second oxide semiconductor layer disposed between the second gate insulating layer and the second gate electrode.

In an embodiment, the first oxide semiconductor layer and the second oxide semiconductor layer may include a same oxide semiconductor.

In an embodiment, the second gate electrode may be directly disposed on the second gate insulating layer.

In an embodiment, the first gate insulating layer may be entirely disposed in the display area.

In an embodiment, the first gate insulating layer may have a shape and a size corresponding to those of the first active layer and be an island-shaped insulating pattern layer covering upper and side surfaces of the first active layer.

In an embodiment, the second gate insulating layer may be an island-shaped insulating pattern layer having a shape and a size corresponding to those of the second gate electrode.

In an embodiment, the first active layer and the second active layer may be disposed on a same layer on the substrate and include a same oxide semiconductor.

In an embodiment, the first transistor and the second transistor may be N-type oxide transistors, and an electron mobility of the second transistor may be higher than an electron mobility of the first transistor.

In an embodiment, the display device may further include an interlayer insulating layer entirely covering the first and second active layers, the first and second gate insulating layers, the first oxide semiconductor layer, and the first and second gate electrodes.

In an embodiment, the first transistor may further include at least one of a first source electrode and a first drain electrode which are disposed on the interlayer insulating layer and connected to different parts of the first active layer.

In an embodiment, the display device may further include a buffer layer disposed between the substrate and a semiconductor layer including the first active layer and the second active layer, and the first transistor may further include a first bottom gate electrode disposed between the substrate and the buffer layer and overlapping the first gate electrode with the first active layer disposed between the first bottom gate electrode and the first gate electrode.

In an embodiment, the first bottom gate electrode may be connected to the first source electrode.

In an embodiment, the second transistor may further include at least one of a second source electrode and a second drain electrode which are disposed on the interlayer insulating layer and connected to different parts of the second active layer.

In an embodiment, the display device may further include a buffer layer disposed between the substrate and a semiconductor layer including the first active layer and the second active layer, and the second transistor may further include a second bottom gate electrode disposed between the substrate and the buffer layer and overlapping the second gate electrode with the second active layer disposed between the second bottom gate electrode and the second gate electrode.

In an embodiment, the second bottom gate electrode may be connected to the second gate electrode.

In an embodiment, the display device may further include a pixel disposed in the display area and including the first transistor, and a driving circuit disposed in the driving circuit area and including the second transistor.

According to an aspect of the disclosure, there is provided a method of manufacturing a display device including, preparing a substrate including a display area and a driving circuit area, forming a first active layer and a second active layer in the display area and the driving circuit area, respectively, on the substrate, sequentially forming a gate insulating layer covering the first active layer and the second active layer and an oxide semiconductor layer covering the gate insulating layer on the substrate, forming a first gate electrode overlapping a part of the first active layer and a second gate electrode overlapping a part of the second active layer, on the oxide semiconductor layer, patterning the gate insulating layer into a first gate insulating layer which entirely covers the first active layer and a second gate insulating layer which partially covers the second active layer, by etching the gate insulating layer, and forming an interlayer insulating layer covering the first active layer, the second active layer, the first gate insulating layer, the second gate insulating layer, the first gate electrode, and the second gate electrode, in the display area and the driving circuit area.

In an embodiment, the method may further include, before patterning the gate insulating layer into the first gate insulating layer and the second gate insulating layer, forming a first oxide semiconductor layer having a shape and a size corresponding to those of the first gate electrode under the first gate electrode by etching the oxide semiconductor layer.

In an embodiment, the method may further include, before forming the first gate electrode and the second gate electrode, forming a first oxide semiconductor layer on a part of the first active layer by etching the oxide semiconductor layer.

In accordance with the display device and the method of manufacturing the display device according to embodiments, the operating characteristics of the first transistor and the second transistor may be differentiated and/or optimized. In embodiments, a first gate insulating layer that entirely or overall covers a first active layer of the first transistor is disposed on the first active layer, so that it is possible to appropriately ensure the threshold voltage and the driving range of the first transistor and stabilize the operating characteristics of the first transistor. In embodiments, a second gate insulating layer that partially covers a second active layer of the second transistor and exposes other portions of the second active layer is disposed on the second active layer, so that it is possible to increase the on-current of the second transistor and improve output characteristics of the second transistor.

Further, in accordance with the display device and the method of manufacturing the display device according to embodiments, a first oxide semiconductor layer may be disposed between a first gate insulating layer and a first gate electrode. Accordingly, the operating characteristics of the first transistor may be stably ensured.

However, effects according to the embodiments are not limited to those above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view illustrating a display device according to an embodiment;

FIG. 2 is a schematic plan view illustrating a display panel of FIG. 1;

FIG. 3 is a schematic diagram of an equivalent circuit of a pixel according to an embodiment;

FIG. 4 is a schematic diagram showing a driving circuit of a first driver according to an embodiment;

FIG. 5 is a schematic diagram of an equivalent circuit of a stage of a driving circuit according to an embodiment;

FIG. 6 is a schematic cross-sectional view illustrating a display panel according to an embodiment;

FIG. 7 is a schematic cross-sectional view illustrating the display panel according to an embodiment;

FIG. 8 is a schematic cross-sectional view illustrating the display panel according to an embodiment;

FIGS. 9, 10, 11, 12, 13, 14, 15, and 16 are schematic cross-sectional views showing a method of manufacturing the display device according to an embodiment; and

FIGS. 17, 18, and 19 are schematic cross-sectional views showing a method of manufacturing the display device according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction D1, the axis of the second direction D2, and the axis of the third direction D3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise.

Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

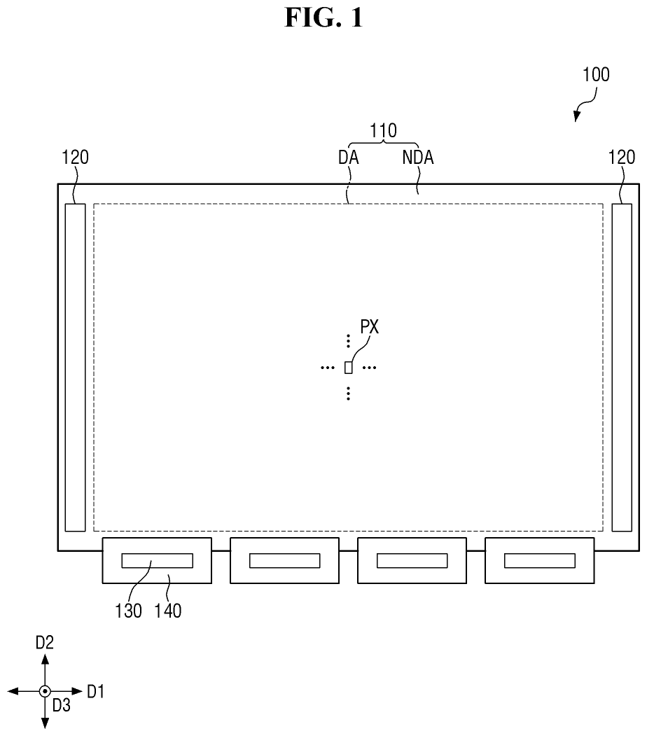

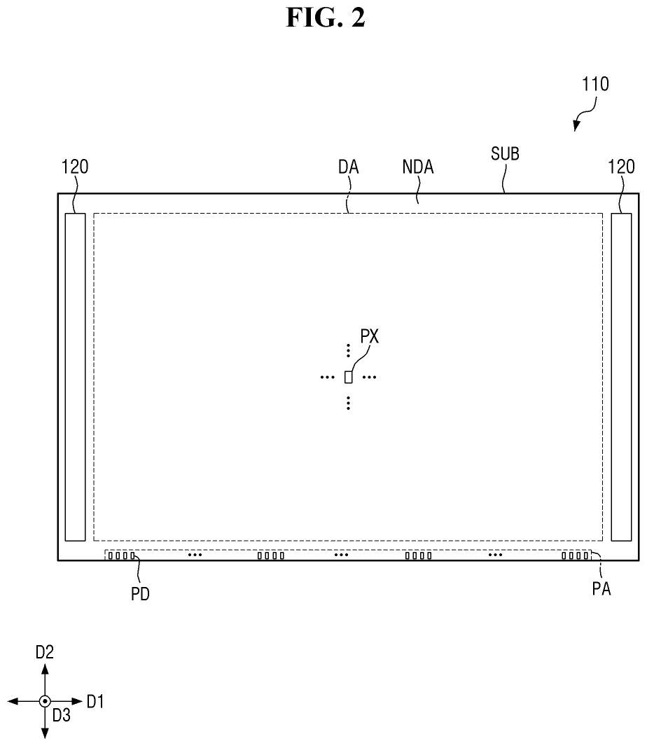

FIG. 1 is a schematic plan view illustrating a display device 100 according to an embodiment. FIG. 2 is a schematic plan view illustrating a display panel 110 of FIG. 1.

Referring to FIGS. 1 and 2, the display device 100 may be a device for displaying a moving image or a still image. The display device 100 may be used as a display screen of various devices, such as a television, a laptop computer, a monitor, a billboard and an Internet-of-Things (IOT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC). These are examples, and the display device 100 may be applicable to various other types of electronic devices.

In an embodiment, the display device 100 may be a light emitting display device such as an organic light emitting display device including an organic light emitting diode, a quantum dot light emitting display device including a quantum dot light emitting layer, an inorganic light emitting display device including an inorganic semiconductor, or an ultra-small light emitting display using an ultra-small light emitting diode such as a micro or nano light emitting diode (micro LED or nano LED), but embodiments are not limited thereto. For example, the display device 100 may be another type of display device other than a light emitting display device. In the following, embodiments in which the display device 100 is an organic light emitting display device will be disclosed.

The display device 100 may include the display panel 110 including pixels PX, and a first driver 120 and a second driver 130 that supplies driving signals to the pixels PX. The display device 100 may further include additional components. For example, the display device 100 may further include a power supply unit for supplying power voltages to the pixels PX, the first driver 120, and the second driver 130, and a timing controller for controlling the operations of the first driver 120 and the second driver 130.

The display panel 110 may include a display area DA and a non-display area NDA (also referred to as a “bezel area”). The display area DA may be an area including the pixels PX to display an image. The non-display area NDA may be an area other than the display area DA, and an image may not be displayed in the non-display area NDA. In an embodiment, the non-display area NDA may be positioned around the display area DA and may surround the display area DA.

In FIGS. 1 and 2, a first direction D1, a second direction D2, and a third direction D3 are defined. In an embodiment, the first direction D1 and the second direction D2 may be perpendicular to each other, the first direction D1 and the third direction D3 may be perpendicular to each other, and the second direction D2 and the third direction D3 may be perpendicular to each other. For example, the first direction D1 may be the horizontal direction (for example, a row direction or X-axis direction) of the display panel 110, and the second direction D2 may be the vertical direction (for example, a column direction or Y-axis direction) of the display panel 110. The third direction D3 may be the thickness direction (for example, a height direction or Z-axis direction) of the display panel 110.

In an embodiment, the display panel 110 may have a rectangular shape in plan view. For example, the display panel 110 may include two first sides extending in the first direction D1 and two second sides extending in the second direction D2 intersecting the first direction D1. Although FIGS. 1 and 2 illustrate the display panel 110 in which the first side in the horizontal direction is longer than the second side in the vertical direction, the shape of the display panel 110 is not limited thereto. For example, the display panel 110 may have a shape in which the second side in the vertical direction is longer than the first side in the horizontal direction, or the lengths of the first side and the second side are substantially the same.

In an embodiment, the display panel 110 may include an angled corner portion at a portion where the first side and the second side meet, but embodiments are not limited thereto. For example, the display panel 110 may include a rounded corner portion at a portion where the first side and the second side meet.

The planar shape of the display panel 110 is not limited to the illustrated rectangular shape, and it may be applied in other shapes. For example, the display panel 110 may have a square shape, a non-quadrilateral polygonal shape, a circular shape, an elliptical shape, an atypical shape, or another shape in plan view.

In an embodiment, the display panel 110 may be substantially flat on the plane defined by the first direction DI and the second direction D2, and may have a uniform thickness in the third direction D3. In another embodiment, the display panel 110 may be provided in a three-dimensional shape having a curved surface or the like.

The display panel 110 may be provided as a panel having rigid characteristics so as not to be substantially deformed, or as a panel having flexible characteristics that can be transformed to be at least partially folded, bent, or rolled. The display panel 110 may be provided to the display device 100 without bending, or may be provided to the display device 100 with being partially bent.

The display panel 110 may include a substrate SUB and the pixels PX disposed on the substrate SUB. The pixels PX may be disposed in the display area DA on the substrate SUB.

The substrate SUB, which is a base member for manufacturing or providing the display panel 110, may form the base surface of the display panel 110. The substrate SUB may include the display area DA and the non-display area NDA disposed around the display area DA.

The display area DA may have various shapes according to embodiments. For example, the display area DA may have a quadrilateral shape, a non-quadrilateral polygonal shape, a circular shape, an elliptical shape, an atypical shape, or another shape. In an embodiment, the display area DA may have a shape corresponding to the shape of the display panel 110, but embodiments are not limited thereto.

The display area DA may include pixel areas where the pixels PX are provided and/or disposed. For example, each pixel PX may be disposed in each pixel area disposed in the display area DA. In an embodiment, the display device 100 may be a light emitting display device, and each pixel PX may include a light emitting element disposed in each emission area and a pixel circuit connected to the light emitting element. In describing embodiments, the term “connect” may include electrical connection and/or physical connection.

Each pixel area may include an emission area where the light emitting element of the corresponding pixel is disposed and where the pixel emits light, and a pixel circuit area where circuit elements constituting/forming the pixel circuit of the corresponding pixel are disposed. The emission area and the pixel circuit area of each pixel PX may overlap each other, but embodiments are not limited thereto.

The pixels PX may be arranged in the display area DA. For example, the pixels PX may be arranged in the display area DA in a stripe structure, a delta structure, a PenTile™ structure, or another arrangement structure.

The non-display area NDA may include a driving circuit area disposed on at least one side of the display area DA and a pad area PA where pads PD are disposed. At least one driver, the pads PD, and/or wires may be disposed in the non-display area NDA.

At least one driver for driving the pixels PX, or a part of the driver may be disposed in the driving circuit area. For example, the circuit elements constituting/forming the first driver 120 may be disposed in the driving circuit area on the substrate SUB. In an embodiment, the circuit elements of the first driver 120 may be formed in the display panel 110 together with the pixels PX.

The pads PD may be disposed in the pad area PA. At least one circuit board 140 may be disposed and/or bonded on the pad area PA. For example, circuit boards 140 connected to different pads PD may be disposed on the pad area PA. The pads PD may include signal pads and power pads for transmitting driving signals and power voltages required for driving the pixels PX and/or the first driver 120 into the display panel 110.

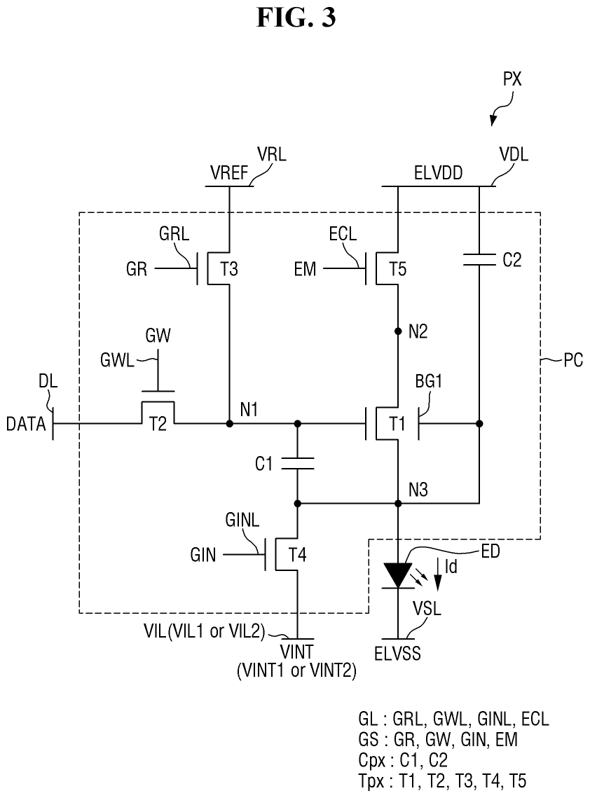

The first driver 120 and the second driver 130 may generate driving signals for controlling operation timing, luminance, and the like of the pixels PX, and may supply the generated driving signals to the pixels PX. For example, the first driver 120 may be a gate driver including a scan driver, and may be connected to the pixels PX through respective gate lines. The first driver 120 may provide gate signals (for example, driving signals that include a first gate signal GW of FIG. 3 and control the operation timing of the pixels PX) to the pixels PX. The second driver 130 may be a data driver including source driving circuits, and may be connected to the pixels PX through respective data lines. The second driver 130 may supply respective data signals to the pixels PX.

In an embodiment, at least one first driver of the first driver 120 or the second driver 130, or a part of the at least one first driver may be embedded in the display panel 110. For example, the first driver 120 or a part of the first driver 120 may be disposed or formed in the non-display area NDA of the display panel 110.

Although FIG. 1 illustrates that the first driver 120 is formed on sides (e.g., opposite sides) of the display area DA (for example, in the non-display area NDA on the left side and the right side of the display area DA), but embodiments are not limited thereto. For example, in another embodiment, the first driver 120 may be disposed only on a side of the display area DA. In another embodiment, a part of the first driver 120 (for example, some of circuit elements constituting/forming the first driver 120) are disposed in the non-display area NDA, and another part of the first driver 120 (for example, the rest of the circuit elements constituting/forming the first driver 120) may be disposed in a non-emission area (for example, an area between emission areas of the pixels PX) disposed in the display area DA.

In an embodiment, the other driver of the first driver 120 and the second driver 130 or a part of the other driver may be disposed or formed outside the display panel 110 to be electrically connected to the display panel 110. For example, the second driver 130 or a part of the second driver 130 may be implemented by a multiple number of integrated circuit chips, and may be disposed on the circuit board 140 electrically connected to the pixels PX of the display panel 110. In an embodiment, the second driver 130 and the timing controller may be integrated into separate integrated circuits, or may be integrated into one integrated chip. The second driver 130 may be implemented as at least one integrated circuit chip and mounted on the non-display area NDA of the display panel 110.

In an embodiment, the display panel 110 may further include a data distributor (for example, a demultiplexer) that is connected between the second driver 130 and the pixels PX of the display area DA and is formed inside the display panel 110. For example, circuit elements (for example, transistors and capacitors) constituting/forming the first driver 120 may be formed in the driving circuit area disposed in the non-display area NDA on the left and/or right side of the display area DA, and circuit elements (for example, transistors) constituting/forming the data distributor may be formed in the driving circuit area disposed in the non-display area NDA on the lower side of the display area DA.

The circuit board 140 may be connected to the display panel 110 through the pads PD. In an embodiment, the circuit board 140 may be a flexible film such as a flexible printed circuit board (FPCB), a printed circuit board (PCB), or a chip on film (COF). In an embodiment, the circuit board 140 may be connected to the timing controller and/or the power supply unit through another circuit board, connector, or the like.

FIG. 3 is a schematic diagram of an equivalent circuit of the pixel PX according to an embodiment. The pixel PX of FIG. 3 is an example, and the structure or type of the pixel PX may be changed in various ways according to embodiments.

Referring to FIG. 3 in addition to FIGS. 1 and 2, the pixel PX may include a light emitting element ED, and a pixel circuit PC connected to the light emitting element ED. The light emitting element ED may be a light source of the pixel PX, and it may be, for example, an organic light emitting diode. The pixel circuit PC may control the emission time point and the luminance of the light emitting element ED.

The pixel circuit PC may include pixel transistors Tpx and at least one pixel capacitor Cpx. For example, the pixel circuit PC may include first to fifth pixel transistors T1 to T5, and first and second pixel capacitors C1 and C2. Although FIG. 3 illustrates an embodiment in which the pixel transistors Tpx are all N-type transistors, the types of pixel transistors Tpx are not limited thereto. For example, at least one pixel transistor Tpx may be formed of a P-type transistor. The structure of the pixel circuit PC or the types of the circuit elements constituting/forming the pixel circuit PC may be changed in various ways according to embodiments.

The pixel circuit PC may supply a driving current Id to the light emitting element ED in response to the driving signals supplied from the first driver 120 and the second driver 130. For example, the pixel circuit PC may supply the driving current Id to the light emitting element ED in response to respective gate signals GS supplied from the first driver 120 through respective gate lines GL and a data signal DATA supplied from the second driver 130 through a data line DL.

The first pixel transistor T1 may be a driving element of the pixel PX, in which a magnitude of a source-drain current (e.g., the driving current Id) is determined according to a gate-source voltage. The second to fifth pixel transistors T2 to T5 may be switching elements that are turned on or off according to their own gate-source voltages (substantially, their own gate voltages). According to the type (for example, P-type or N-type) and/or operating conditions of each of the first to fifth pixel transistors T1 to T5, a first electrode of each of the first to fifth pixel transistors T1 to T5 may be a drain electrode or a source electrode, and a second electrode thereof may be an electrode different from the first electrode. For example, in case that the first electrode is a drain electrode, the second electrode may be a source electrode.

The pixel PX may be connected to a first gate line GWL (e.g., GWL1, GWL2, GWL3, GWL4, . . . ) that transmits the first gate signal GW (e.g., a scan signal), a second gate line GINL that transmits a second gate signal GIN, a third gate line GRL that transmits a third gate signal GR, an emission control line ECL that transmits an emission control signal EM, and the data line DL that transmits the data signal DATA. Further, the pixel PX may be connected to a first pixel power line VDL that transmits a first pixel voltage ELVDD (also referred to as “a first pixel power voltage”), and a second pixel power line VSL that transmits a second pixel voltage ELVSS (also referred to as “a second pixel power voltage”). In an embodiment, the pixel PX may be further connected to an initialization power line VIL that transmits an initialization voltage VINT (also referred to as “third pixel power voltage”), and a reference power line VRL that transmits a reference voltage VREF (also referred to as “fourth pixel power voltage”). In an embodiment, the initialization power line VIL may include initialization power lines VIL (e.g., a first initialization power line VIL1 and a second initialization power line VIL2) for transmitting the initialization voltages VINT having different magnitudes (e.g., a first initialization voltage VINT1 and a second initialization voltage VINT2).

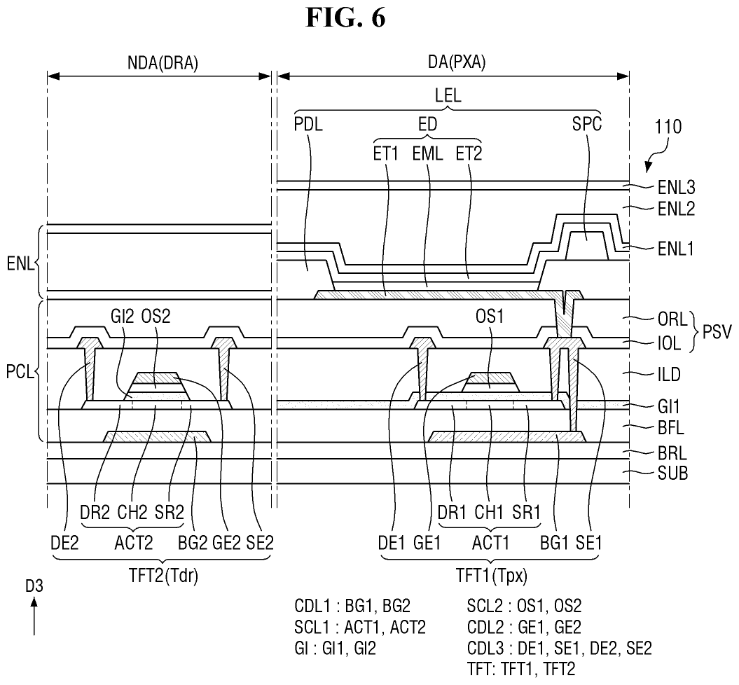

In an embodiment, the first to fifth pixel transistors T1 to T5 may be disposed in respective pixel areas (e.g., a pixel area PXA of any one pixel PX disposed in the display area DA of FIG. 6), and may be oxide transistors (also referred to as “oxide semiconductor transistors”) including an oxide semiconductor (for example, an oxide semiconductor material). For example, the active layer (also referred to as “semiconductor pattern layer” or “active pattern layer”) of each of the first to fifth pixel transistors T1 to T5 may be formed of an oxide semiconductor. However, embodiments are not limited thereto. For example, at least one pixel transistor Tpx may be formed of a semiconductor material (for example, amorphous silicon or polysilicon) other than an oxide semiconductor.

The oxide semiconductor may have high carrier mobility (for example, a high electron mobility in the case of an N-type transistor) and a low leakage current, so although a driving time of the oxide transistor is long, a voltage drop may not be large. For example, the pixel PX including an oxide transistor may be driven at a low frequency because the change in the luminance and/or the color of an image due to a voltage drop is not significant in case that it is driven at a low frequency. In the case of the display device 100 in which the first to fifth pixel transistors T1 to T5 include an oxide semiconductor, the leakage current of the pixel PX may be reduced or prevented and the power consumption may be reduced.

In an embodiment, a bottom gate electrode (also referred to as “counter gate electrode” or “lower electrode”) may be disposed under the active layer constituting/forming at least one pixel transistor Tpx (for example, at least one of the first to fifth pixel transistors T1 to T5). For example, the bottom gate electrode may be disposed under the active layer of the pixel transistor Tpx including an oxide semiconductor. The bottom gate electrode may be disposed to face the gate electrode (for example, a top gate electrode) with the active layer of the corresponding pixel transistor Tpx interposed between the bottom gate electrode and the gate electrode.

In describing embodiments, the bottom gate electrode provided to at least one pixel transistor Tpx is referred to as “a first bottom gate electrode BG1.” By providing the first bottom gate electrode BG1 to the pixel transistor Tpx, it is possible to prevent or reduce the change in the amount of current of the pixel transistor Tpx due to light, and to stabilize the operating characteristics of the pixel transistor Tpx.

The first pixel transistor T1 may include a gate electrode connected to a first node N1 (or a gate node), a first electrode (for example, a drain electrode) connected to a second node N2, and a second electrode (for example, a source electrode) connected to a third node N3. In an embodiment, the first pixel transistor T1 may further include the first bottom gate electrode BG1 (or a first back-gate electrode). For example, the first pixel transistor T1 may further include the first bottom gate electrode BG1 connected to the third node N3. In case that the first bottom gate electrode BG1 of the first pixel transistor T1 is connected to the third node N3 similarly to the second electrode of the first pixel transistor T1, the operating characteristics of the first pixel transistor T1 may be improved. The first electrode of the first pixel transistor T1 may be connected to the first pixel power line VDL via the fifth pixel transistor T5, and the second electrode thereof may be connected to the light emitting element ED. The first pixel transistor T1 may function as a driving element of the pixel PX, and may control the magnitude (for example, the amount of current) of the driving current Id flowing to the light emitting element ED in response to the data signal DATA transmitted according to the switching operation of the second pixel transistor T2.

In an embodiment, at least one pixel transistor Tpx among the second to fifth pixel transistors T2 to T5 may also include a bottom gate electrode (for example, each first bottom gate electrode BG1). In an embodiment, the bottom gate electrode of the at least one pixel transistor Tpx may be connected to an electrode (for example, a gate electrode) of the corresponding pixel transistor Tpx.

The second pixel transistor T2 may include a gate electrode connected to the first gate line GWL, a first electrode connected to the data line DL, and a second electrode connected to the first node N1. The second pixel transistor T2 may be turned on by the first gate signal GW (for example, the gate-on voltage of the first gate signal GW) transmitted to the first gate line GWL to connect the data line DL and the first node N1. Accordingly, the data signal DATA transmitted through the data line DL may be sent to the first node N1.

The third pixel transistor T3 may include a gate electrode connected to the third gate line GRL, a first electrode connected to the reference power line VRL, and a second electrode connected to the first node N1. The third pixel transistor T3 may be turned on by the third gate signal GR transmitted through the third gate line GRL and transmit the reference voltage VREF transmitted to the reference power line VRL to the first node N1.

The fourth pixel transistor T4 may include a gate electrode connected to the second gate line GINL, a first electrode connected to the third node N3, and a second electrode connected to the initialization power line VIL. The fourth pixel transistor T4 may be turned on by the second gate signal GIN transmitted through the second gate line GINL and transmit the initialization voltage VINT transmitted to the initialization power line VIL to the third node N3.

The fifth pixel transistor T5 may include a gate electrode connected to the emission control line ECL, a first electrode connected to the first pixel power line VDL, and a second electrode connected to the second node (or the first electrode of the first pixel transistor T1). The fifth pixel transistor T5 may be turned on by the emission control signal EM (for example, the gate-on voltage of the emission control signal EM) transmitted to the emission control line ECL to control the emission time point of the pixel PX.

The first pixel capacitor C1 may be connected between the first node NI and the third node N3. For example, the first pixel capacitor C1 may be connected between the second electrode and the gate electrode of the first pixel transistor T1. The first pixel capacitor C1 may be a storage capacitor of the pixel PX, and may store therein a threshold voltage of the first pixel transistor T1 and a voltage corresponding to the data signal DATA (e.g., a data voltage).

The second pixel capacitor C2 may be connected between the first pixel power line VDL and the third node N3. In an embodiment, the capacity of the second pixel capacitor C2 may be smaller than that of the first pixel capacitor C1.

The light emitting element ED may be connected between the third node N3 and the second pixel power line VSL. For example, the light emitting element ED may include a first electrode (for example, an anode electrode), a second electrode (for example, a cathode electrode) facing the first electrode, and a light emitting layer disposed between the first electrode and the second electrode. The first electrode of the light emitting element ED may be connected to the third node N3. The second electrode of the light emitting element ED may be connected to the second pixel power line VSL. In an embodiment, the second electrode of the light emitting element ED may be a common electrode shared by the pixels PX. The light emitting element ED may emit light at a luminance corresponding to the driving current Id during a time period in which the driving current Id is supplied from the pixel circuit PC.

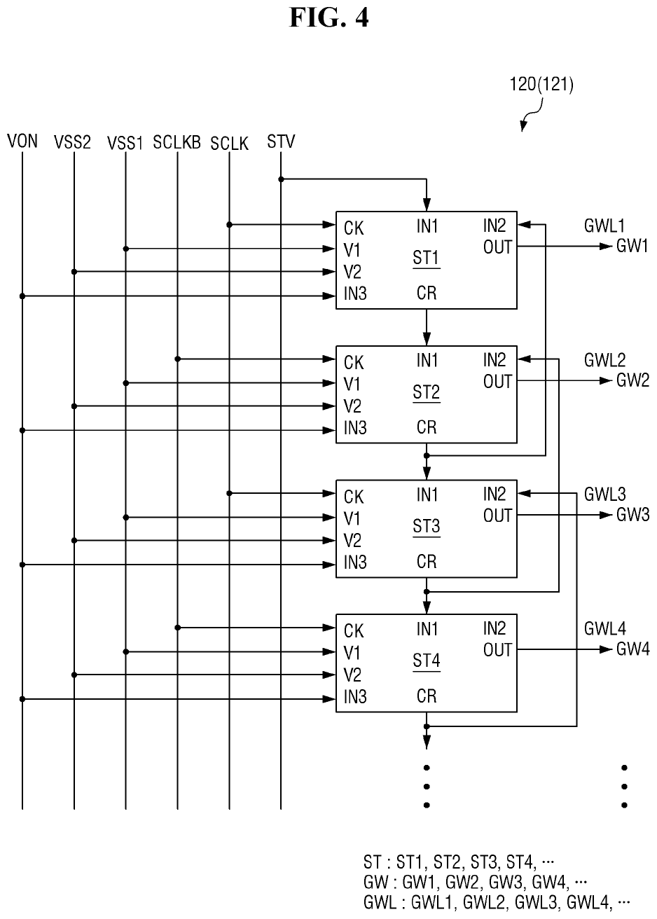

FIG. 4 is a diagram showing a driving circuit 121 of the first driver 120 according to an embodiment. FIG. 4 shows one type of driving circuit 121 included in the first driver 120 (or constituting/forming the first driver 120) as an example for showing the configuration of the first driver 120. In an embodiment, the driving circuit 121 may be a scan driving circuit (or a scan driver) that outputs the first gate signals GW of the pixels PX, but embodiments are not limited thereto. For example, the driving circuit 121 of FIG. 4 is illustrated as an example, and the type, structure, number, and/or input/output signals of the first driver 120 or the driving circuit 121 constituting/forming the first driver 120 may vary in various ways according to embodiments.

In the following description, the term “previous stages (or previous-step stages)” may refer to stages that generate the first gate signals GW whose phase is faster than the first gate signal GW outputted at a specific stage as a reference. Also, the term “next stages (or next-step stages)” may refer to stages that generate the first gate signals GW whose phase is later than the first gate signal GW outputted at the specific stage as the reference.

Referring to FIG. 4 in addition to FIGS. 1 to 3, the driving circuit 121 may include stages ST.

Each of the stages ST may receive multiple driving power voltages and multiple external signals. The stages ST may output the respective first gate signals GW based on the multiple driving power voltages (or driving voltages) and the multiple external signals inputted thereto. In an embodiment, the driving power voltages may include at least one of a first driving voltage VON (also referred to as “control voltage”) that is a high potential voltage, a second driving voltage VSS1 (also referred to as “a first driving power voltage” or “a first low-potential driving voltage”) that is a first low-potential voltage, or a third driving voltage VSS2 (also referred to as “a second driving power voltage” or “a second low-potential driving voltage”) that is a second low-potential voltage. For example, the multiple external signals may include at least one of a scan start signal STV, a carry signal inputted from the previous stage, a reset signal inputted from the next stage, or a scan clock signal (e.g., a first scan clock signal SCLK and a second scan clock signal SCLKB), but embodiments are not limited thereto. In an embodiment, the third driving voltage VSS2 may have a potential lower than that of the second driving voltage VSS1.

The first gate signal GW (e.g., GW1, GW2, GW3, GW4, . . . ) outputted from each stage ST (for example, a first gate signal GW1 outputted from a first stage ST1 of FIG. 4) may be supplied to the next stage (for example, a second stage ST2) as a carry signal. Each stage ST may output the first gate signal GW to the first gate line GWL connected thereto in response to a carry signal (e.g., a first carry signal) inputted from the previous stage. Among the stages ST, the first stage ST1 may receive the scan start signal STV from the outside as the carry signal.

The first gate signal GW outputted from each stage ST may be supplied to the previous stage as a reset signal (e.g., a second carry signal). Each stage ST may transit the potential of an output node from a high-potential voltage to a second low-potential voltage (e.g., the third driving voltage VSS2) in response to the reset signal inputted from the next stage.

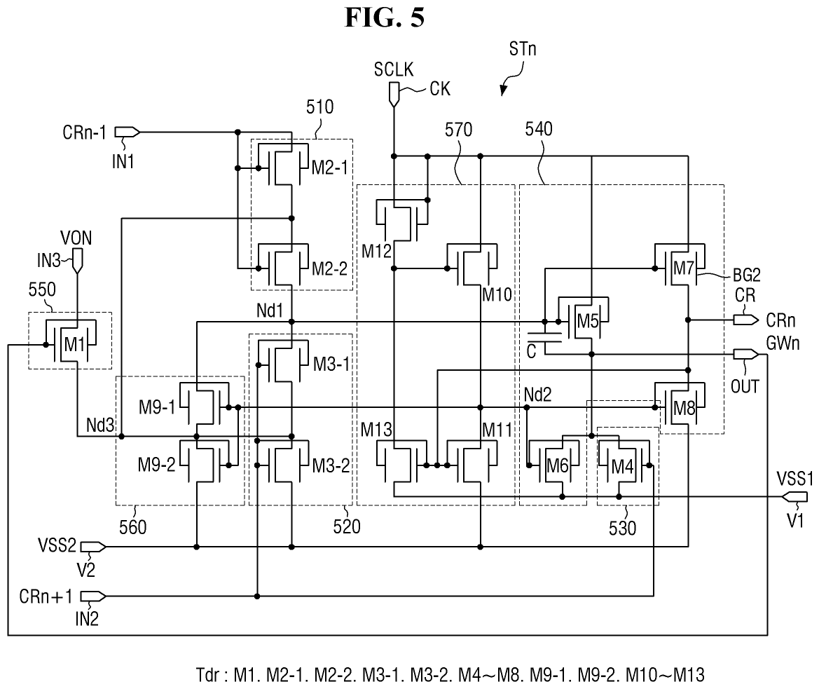

The stages ST may output the first gate signals GW in response to the scan start signal STV. For example, the stages ST may sequentially output the first gate signals GW to the first gate lines GWL in response to the scan start signal STV. For example, the nth (n is a natural number) stage (for example, the n^{th} stage STn of FIG. 5) may output the n^{th} first gate signal GW (for example, the n^{th} scan signal GWn of FIG. 5) to the n^{th} first gate line GWL. The scan start signal STV for controlling the output timing of the first gate signal GW1 (for example, a first scan signal) may be supplied to the first stage ST1.

Each of the stages ST may include a first input terminal IN1, a second input terminal IN2, a third input terminal IN3, a scan clock input terminal CK, a first power input terminal V1, a second power input terminal V2, a carry output terminal CR, and an output terminal OUT.

Each of the stages ST may receive the first scan clock signal SCLK or the second scan clock signal SCLKB through the scan clock input terminal CK. For example, the odd-numbered stages ST1, ST3, . . . may receive the first scan clock signal SCLK, in case that the even-numbered stages ST2, ST4, . . . receive the second scan clock signal SCLKB.

The first scan clock signal SCLK may be a square wave signal (or pulse signal) that repeats a logic high level and a logic low level. The logic high level may correspond to a gate-on voltage, and the logic low level may correspond to a gate-off voltage. For example, the logic high level may be a gate-high voltage with a voltage value in a range of about 10V to about 30V, and the logical low level may be a gate-low voltage with a voltage value in a range of about-16V to about-3V.

The second scan clock signal SCLKB may be a square wave signal (or pulse signal) that repeats the logic high level and the logic low level. In an embodiment, the second scan clock signal SCLKB may be set as a signal having the same cycle as the first scan clock signal SCLK but having an inverted phase. However, this is an example, and the waveform relationship between the first scan clock signal SCLK and the second scan clock signal SCLKB is not limited thereto. By way of example, a part of the logic high level period of the first scan clock signal SCLK and a part of the logic high level period of the second scan clock signal SCLKB may overlap.

For example, the number of the scan clock signals supplied to one stage is not limited to the above example. For example, two or more scan clock signals may be applied to each of the stages ST.

The first input terminal IN1 may receive the scan start signal STV or a carry signal of the previous stage. For example, the scan start signal STV may be applied to the first input terminal IN1 of the first stage ST1, and the carry signal of the previous stage may be applied to the first input terminal IN1 of each of the stages ST2, ST3, ST4, . . . other than the first stage ST1.

The second input terminal IN2 may receive a carry signal of the next stage. For example, the carry signal of the next stage may be one of the carry signals supplied after the lapse of a selected time from the output of the carry signal of the current stage.

The third input terminal IN3 may receive the first driving voltage VON. In an embodiment, the first driving voltage VON may be a high-potential voltage to be supplied to the source electrode of at least one transistor included in each of the stages ST. For example, the first driving voltage VON may be a constant voltage, which is similar/equal to the logic high level (e.g., the gate-on voltage) of the first scan clock signal SCLK. For example, the first driving voltage VON may have a voltage value in a range of about 10V to about 30V.

In an embodiment, the first driving voltage VON and the first scan clock signal SCLK (or second scan clock signal SCLKB) may be the same as each other. For example, each of the stages ST may receive the same clock signal through the scan clock input terminal CK and the third input terminal IN3.

The carry output terminal CR may output a carry signal. The carry signal may be provided to the first input terminal IN1 of the next stage.

The output terminal OUT may output the first gate signal GW generated at each stage ST. The first gate signal GW may be supplied to the pixel PX through the first gate line GWL corresponding thereto.

The first power input terminal V1 may be supplied with the second driving voltage VSS1, and the second power input terminal V2 may be supplied with the third driving voltage VSS2. The second driving voltage VSS1 and the third driving voltage VSS2 may be set to be the gate-off voltage. In an embodiment, the second driving voltage VSS1 and the third driving voltage VSS2 may be the same. In an embodiment, the voltage level of the third driving voltage VSS2 may be lower than the voltage level of the second driving voltage VSS1. For example, the second driving voltage VSS1 may be set in a range of about −14V to about −1V, and the third driving voltage VSS2 may be set in a range of about −16V to about −3V.

FIG. 5 is a schematic diagram of an equivalent circuit of a stage ST or STn of the driving circuit 121 according to an embodiment. FIG. 5 shows the n^{th} stage STn included in the aforementioned driving circuit 121 (or constituting/forming the driving circuit 121) as an example for showing the configuration of the driving circuit 121. The n^{th} stage STn of FIG. 5 is an example, and the structure, input/output signals, and/or operating method of the n^{th} stage STn may be variously changed according to embodiments.

Although FIG. 5 shows an embodiment in which driver transistors Tdr constituting/forming the n^{th} stage STn are N-type transistors, the types of the driver transistors Tdr are not limited thereto. For example, at least one driver transistor Tdr may be formed of a P-type transistor.

Referring to FIG. 5 in addition to FIGS. 1 to 4, the n^{th} stage STn may include a first input unit 510, a second input unit 520, a first controller 530, an output unit 540, and a leakage controller 550. In an embodiment, the n^{th} stage STn may further include a second controller 560 and a third controller 570.

In an embodiment, the driver transistors Tdr included in the n^{th} stage STn may be disposed in the driving circuit area (for example, the driving circuit area where the first driver 120 is disposed in the non-display area NDA of the display panel 110) of the display panel 110. In an embodiment, the driver transistors Tdr may be oxide transistors including an oxide semiconductor (for example, an oxide semiconductor material). For example, an active layer of each of the driver transistors Tdr may be formed of an oxide semiconductor. In an embodiment, the driver transistors Tdr and the pixel transistors Tpx may be formed simultaneously of the same oxide semiconductor. For example, active layers of the driver transistors Tdr and the pixel transistors Tpx may include the same oxide semiconductor, and may be disposed on the same layer (e.g., buffer layer BFL) on the substrate SUB. However, embodiments are not limited thereto. For example, at least one driver transistor Tdr may be formed of a semiconductor material (for example, amorphous silicon or polysilicon) other than an oxide semiconductor.

Each of the driver transistors Tdr may or may not include a bottom gate electrode (for example, a bottom gate electrode facing (or overlapping) the gate electrode with each active layer interposed between the bottom gate electrode and the gate electrode). In an embodiment, the driver transistors Tdr may include the respective bottom gate electrodes disposed under the respective active layers. In describing the following embodiments, the bottom gate electrode provided to each of the driver transistors Tdr is referred to as “a second bottom gate electrode BG2.” By providing the respective second bottom gate electrodes BG2 to the driver transistors Tdr, the operating characteristics of the driver transistors Tdr may be improved and/or stabilized.

In an embodiment, at least one driver transistor Tdr may include the second bottom gate electrode BG2 (or a second back-gate electrode) connected to the gate electrode of the corresponding transistor. For example, some driver transistors Tdr (for example, buffer transistors) including the driver transistors Tdr of the output unit 540 that perform a pull-up or pull-down operation, or all the driver transistors Tdr constituting/forming the stage STn may be transistors of a double gate structure including the respective second bottom gate electrodes BG2 connected to the respective gate electrodes. FIG. 5 illustrates the stage STn in which all the driver transistors Tdr are formed in a double gate structure.

By forming the driver transistors Tdr in a double gate structure, it is possible to improve the operating characteristics of the driver transistors Tdr. For example, by forming the driver transistors Tdr in a double gate structure in which each gate electrode and each second bottom gate electrode BG2 are connected, it is possible to improve off characteristics and switching speeds of the driver transistors Tdr.

The first input unit 510 may control the voltage of a first node Nd1 in response to the scan start signal STV or a carry signal CRn−1 of the previous stage supplied to the first input terminal IN1. The voltage of the first node Nd1 may be a voltage for controlling the outputs of the n^{th} first gate signal (hereinafter referred to as “n^{th} scan signal GWn”) and the n^{th} carry signal CRn. For example, the voltage of the first node Nd1 may be a voltage for controlling the pull-up of the n^{th} carry signal CRn and the n^{th} scan signal GWn.

In an embodiment, the first input unit 510 may include second driver transistors (for example, a second-first driver transistor M2-1 and a second-second driver transistor M2-2) connected in series between the first input terminal IN1 and the first node Nd1. Gate electrodes of the second driver transistors M2-1 and M2-2 may be connected to the first input terminal IN1 in common.

The first input unit 510 may transmit the gate-on voltage (e.g., logic high level) of the (n−1)^{th} carry signal CRn−1 to the first node Nd1. For example, the first input unit 510 may precharge the voltage of the first node Nd1 by using the gate-on voltage of the (n−1)^{th} carry signal CRn−1.

A common node between the second driver transistors M2-1 and M2-2 may correspond to a third node Nd3. For example, the common node between the second driver transistors M2-1 and M2-2 may be connected to the third node Nd3.

In case that the voltage of the first node Nd1 is high at the level of the gate-on voltage, a leakage current may be generated from the first node Nd1 to the first input unit 510 in case that the voltage of the common node between the second driver transistors M2-1 and M2-2 is lower than a certain reference value. For example, in case that the threshold voltage is negatively shifted due to degradation of the second driver transistors M2-1 and M2-2, a leakage current may be generated from the first node Nd1 to the first input unit 510.

In each oxide transistor, a threshold voltage Vth may be shifted to a negative value (e.g., negatively shifted) due to degradation or the like. For example, the oxide transistor may suffer an increase of the leakage current in a turn-off state, so that the stage STn may operate abnormally.

A high voltage at the level of the gate-on voltage may be applied to the common node between the second driver transistors M2-1 and M2-2 in the state that the first node Nd1 is charged with the gate-on voltage. For example, the (n−1)^{th} carry signal CRn−1 may have the gate-off voltage, and the gate-off voltage may be supplied to gate electrodes of the second driver transistors M2-1 and M2-2. Therefore, a gate-source voltage Vgs of the second-second driver transistor M2-2 may be maintained at a very low value (e.g., a negative value), and although the second driver transistors M2-1 and M2-2 are degraded, a current leakage from the first node Nd1 to the first input unit 510 may be prevented.

The second input unit 520 may control the voltage of the first node Nd1 in response to a reset signal (e.g., (n+1)^{th} carry signal CRn+1) of the next stage. In an embodiment, the second input unit 520 may provide a voltage of the third driving voltage VSS2 to the first node Nd1 in response to the (n+1)^{th} carry signal CRn+1. For example, the second input unit 520 may discharge the voltage of the first node Nd1 having a selected high-potential voltage.

The second input unit 520 may include third driver transistors (for example, a third-first driver transistor M3-1 and a third-second driver transistor M3-2) connected in series between the first node Nd1 and the second power input terminal V2. Gate electrodes of the third driver transistors M3-1 and M3-2 may be connected to the second input terminal IN2 in common.

A common node between the third driver transistors M3-1 and M3-2 may correspond to the third node Nd3. For example, the common node between the third driver transistors M3-1 and M3-2 may be connected to the third node Nd3.

The first controller 530 may control the voltage of the output terminal OUT that outputs the n^{th} scan signal GWn in response to the (n+1)^{th} carry signal CRn+1. In an embodiment, the first controller 530 may provide a voltage of the second driving voltage VSS1 to the output terminal OUT in response to the (n+1)^{th} carry signal CRn+1.

In an embodiment, the first controller 530 may include a fourth driver transistor M4 connected between the output terminal OUT and the first power input terminal V1. A gate electrode of the fourth driver transistor M4 may be connected to the second input terminal IN2. The fourth driver transistor M4 may discharge the voltage of the output terminal OUT to the voltage of the second driving voltage VSS1.

The output unit 540 may be connected to the scan clock input terminal CK, the first power input terminal V1, and the second power input terminal V2. The output unit 540 may output the n^{th} scan signal GWn corresponding to the first scan clock signal SCLK and the nth carry signal CRn to the output terminal OUT and the carry output terminal CR, respectively, in response to the voltage of the first node Nd1 and the voltage of a second node Nd2. The voltage of the second node Nd2 may control the gate-off voltage (e.g., logic low level) states of the nth scan signal GWn and the n^{th} carry signal CRn. For example, the voltage of the second node Nd2 may be a voltage for controlling the pull-down of the n^{th} carry signal CRn and the n^{th} scan signal GWn. In an embodiment, the output unit 540 may include fifth to eighth driver transistors M5 to M8 and a driver capacitor C.

The fifth driver transistor M5 may be connected between the scan clock input terminal CK and the output terminal OUT. The fifth driver transistor M5 may include a gate electrode connected to the first node Nd1. The fifth driver transistor M5 may supply the gate-on voltage to the output terminal OUT in response to the voltage of the first node Nd1. For example, the fifth driver transistor M5 may function as a pull-up buffer.

The sixth driver transistor M6 may be connected between the output terminal OUT and the first power input terminal V1. The sixth driver transistor M6 may include a gate electrode connected to the second node Nd2. The sixth driver transistor M6 may supply the gate-off voltage to the output terminal OUT in response to the voltage of the second node Nd2. For example, the sixth driver transistor M6 may hold the voltage of the output terminal OUT at the gate-off voltage level (or logic low level).

The seventh driver transistor M7 may be connected between the scan clock input terminal CK and the carry output terminal CR. The seventh driver transistor M7 may include a gate electrode connected to the first node Nd1. The seventh driver transistor M7 may supply the gate-on voltage to the carry output terminal CR in response to the voltage of the first node Nd1. For example, the seventh driver transistor M7 may function as a pull-up buffer.

The eighth driver transistor M8 may be connected between the carry output terminal CR and the second power input terminal V2. The eighth driver transistor M8 may include a gate electrode connected to the second node Nd2. The eighth driver transistor M8 may supply the gate-off voltage to the carry output terminal CR in response to the voltage of the second node Nd2. For example, the eighth driver transistor M8 may hold the voltage of the carry output terminal CR at the gate-off voltage level (e.g., logic low level).

The driver capacitor C may be connected between the first node Nd1 and the output terminal OUT. The driver capacitor C may function as a boosting capacitor. For example, the driver capacitor C may raise (or bootstrap) the voltage of the first node Nd1 in response to a voltage rise of the output terminal OUT in case that the fifth driver transistor M5 is turned on. Accordingly, the fifth driver transistor M5 may stably maintain a turn-on state for a selected period of time.

The second controller 560 may hold the voltage of the first node Nd1 to a gate-off voltage in response to the voltage of the second node Nd2. In an embodiment, the second controller 560 may provide a voltage of the third driving voltage VSS2 (e.g., the gate-off voltage) to the first node Nd1 in response to the voltage of the second node Nd2.

In an embodiment, the second controller 560 may include ninth driver transistors (e.g., a ninth-first driver transistor M9-1 and a ninth-second driver transistor M9-2) connected in series between the first node Nd1 and the second power input terminal V2. Gate electrodes of the ninth driver transistors M9-1 and M9-2 may be connected to the second node Nd2 in common.

A common node between the ninth driver transistors M9-1 and M9-2 may correspond to the third node Nd3. For example, the common node between the ninth driver transistors M9-1 and M9-2 may be electrically connected to the third node Nd3.

Although the two second driver transistors M2-1 and M2-2, the two third driver transistors M3-1 and M3-2, and the two ninth driver transistors M9-1 and M9-2 are illustrated in FIG. 5, the number of the driver transistors Tdr connected in series is not limited thereto. For example, in case that three or more third driver transistors are connected in series, at least one common node between these third driver transistors may be electrically connected to the third node Nd3.

The third controller 570 may control the voltage of the second node Nd2 in response to the first scan clock signal SCLK and the n^{th} carry signal CRn. In an embodiment, the third controller 570 may transmit the first scan clock signal SCLK to the second node Nd2 in response to the first scan clock signal SCLK, and then supply the gate-off voltage to the second node Nd2 in response to the n^{th} carry signal CRn.

The voltage of the second node Nd2 may control the gate-off voltage (e.g., logic low level) states of the n^{th} scan signal GWn and the n^{th} carry signal CRn. For example, the voltage of the second node Nd2 may be a voltage for controlling the pull-down of the n^{th} carry signal CRn and the n^{th} scan signal GWn.

The third controller 570 may include tenth to thirteenth driver transistors M10 to M13.

The tenth driver transistor M10 may be connected between the scan clock input terminal CK and the second node Nd2. A gate electrode of the tenth driver transistor M10 may be connected to a common node of the twelfth and thirteenth driver transistors M12 and M13. The tenth driver transistor M10 may supply the first scan clock signal SCLK to the second node Nd2 in response to the first scan clock signal SCLK.

The eleventh driver transistor M11 may be connected between the second node Nd2 and the second power input terminal V2.

The twelfth and thirteenth driver transistors M12 and M13 may be connected in series between the scan clock input terminal CK and the first power input terminal V1. A gate electrode of the twelfth driver transistor M12 may be connected to the scan clock input terminal CK. Gate electrodes of the eleventh and thirteenth driver transistors M11 and M13 may be connected to the carry output terminal CR in common.

In case that the n^{th} carry signal CRn is outputted (for example, in case that the n^{th} carry signal CRn has the gate-on voltage), the thirteenth driver transistor M13 may be turned on to turn off the tenth driver transistor M10, and the eleventh driver transistor M11 may be turned on to supply a voltage of the third driving voltage VSS2 to the second node N2. Accordingly, in case that the n^{th} carry signal CRn is outputted, the second node Nd2 may have a gate-off voltage.

In an embodiment, the voltage level of the third driving voltage VSS2 may be lower than the voltage level of the second driving voltage VSS1. For example, the voltage of the third driving voltage VSS2 lower than the voltage of the second driving voltage VSS1 may be provided to the second node Nd2 by the operation of the eleventh driver transistor M11. This may be performed to prevent an unintended operation of the sixth driver transistor M6 and/or the eighth driver transistor M8 due to the ripple of the voltage of the second node Nd2 in case that the voltage of the second node Nd2 changes from the gate-on voltage to the gate-off voltage. Accordingly, an electrode of the eleventh driver transistor M11 may be connected to the third driving voltage VSS2 lower than the voltage of the second driving voltage VSS1.

The leakage controller 550 may supply the first driving voltage VON supplied to the third input terminal IN3 to the first input unit 510, the second input unit 520, and the second controller 560 in response to one of the n^{th} scan signal GWn and the n^{th} carry signal CRn. In an embodiment, the leakage controller 550 may include a first driver transistor MI connected between the third input terminal IN3 and the third node Nd3. The first driver transistor MI may include a gate electrode that receives the n^{th} scan signal GWn.

The first driver transistor MI may supply, in response to the n^{th} scan signal GWn, the first driving voltage VON to common nodes of the driver transistors Tdr respectively connected in series to the first node Nd1. Accordingly, in case that the first node Nd1 is charged (for example, in case that the voltage of the first node Nd1 is boosted), the first driving voltage VON of a high potential may be applied to an electrode of the second driver transistor (e.g., the second-second driver transistor M2-2), an electrode of the third driver transistor (e.g., the third-first driver transistor M3-1), and an electrode of the ninth driver transistor (e.g., the ninth-first driver transistor M9-1). In case that the first node Nd1 is being charged, the third node Nd3 may be charged with the high-potential voltage by the first driving voltage VON. Therefore, in case that the voltage of the first node Nd1 is boosted, the gate-source voltage Vgs of each of the second-second driver transistor M2-2, the third-first driver transistor M3-1, and the ninth-first driver transistor M9-1 may have a negative value, and the gate-source voltage Vgs of each of the second-second driver transistor M2-2, the third-first driver transistor M3-1, and the ninth-first driver transistor M9-1 may be maintained at a value much smaller than a threshold voltage. Accordingly, the leakage current from the first node Nd1 through the second-second driver transistor M2-2, the third-first driver transistor M3-1, and the ninth-first driver transistor M9-1 may be prevented or reduced.

FIG. 6 is a schematic cross-sectional view illustrating the display panel 110 according to an embodiment. For example, FIG. 6 illustrates a part of the display area DA and a part of the non-display area NDA of the display panel 110.

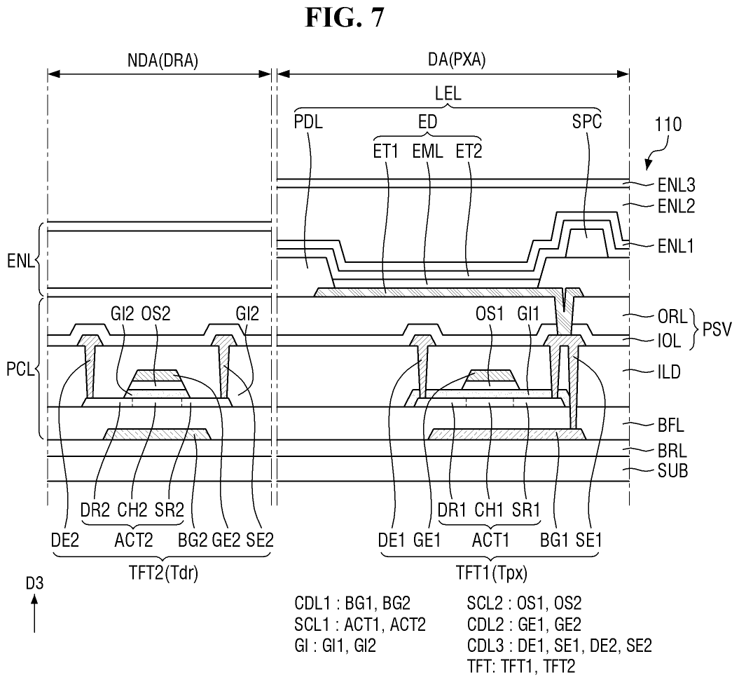

FIG. 7 is a schematic cross-sectional view illustrating the display panel 110 according to an embodiment. For example, FIG. 7 shows a part of the display area DA and a part of the non-display area NDA of the display panel 110, and shows an embodiment different from the embodiment of FIG. 6 in relation to a first gate insulating layer GI1.

In FIGS. 6 and 7, as an example of circuit elements that may be provided or disposed in a panel circuit layer PCL of the display panel 110, any one pixel transistor Tpx (also referred to as “a first transistor TFT1”) and any one driver transistor Tdr (also referred to as “a second transistor TFT2”) are illustrated.

For example, FIGS. 6 and 7 illustrate a light emitting display panel including the light emitting element ED (for example, an organic light emitting diode) as an example of the display panel 110 to which embodiments may be applied. However, embodiments are not limited thereto. For example, the display panel 110 may include a light emitting element of another type and/or structure, or may be a display panel of another type and/or structure other than the light emitting display panel.

Referring to FIGS. 6 and 7 in addition to FIGS. 1 to 5, the display panel 110 may include the substrate SUB (also referred to as “base member” or “base layer”), the panel circuit layer PCL, a light emitting element layer LEL, and an encapsulation layer ENL. The panel circuit layer PCL, the light emitting element layer LEL, and the encapsulation layer ENL may be disposed or provided to overlap each other on the substrate SUB. For example, with respect to the display area DA, the panel circuit layer PCL, the light emitting element layer LEL, and the encapsulation layer ENL may be sequentially arranged or formed on the substrate SUB along the third direction D3. However, embodiments are not limited thereto, and the positions of the panel circuit layer PCL, the light emitting element layer LEL, and/or the encapsulation layer ENL may be changed.

In an embodiment, the display panel 110 may further include additional elements provided above and/or under the encapsulation layer ENL. For example, the display panel 110 may further include at least one of a sensor layer (for example, a touch sensor layer), an optical layer (for example, a color filter layer and/or a wavelength conversion layer), or a passivation layer (for example, a passivation film, an insulating layer, an upper substrate, and/or a window). Each of the sensor layer, the optical layer, and/or the passivation layer may be provided above the encapsulation layer ENL or may be provided between the light emitting element layer LEL and the encapsulation layer ENL.

The substrate SUB, which is a base member for forming the display panel 110, may be a substrate (or film) having rigid or flexible characteristics. In an embodiment, the substrate SUB may be a substrate including an insulating material such as glass or the like and having rigid characteristics, and may not be bent. In another embodiment, the substrate SUB may be a flexible substrate that includes polyimide or another insulating material and may be transformed to be bent, folded, or rolled, and may or may not be bent. The type and/or material of the substrate SUB may change according to embodiments.

The substrate SUB may include the display area DA and the non-display area NDA. In an embodiment, the display area DA may include the pixel areas PXA corresponding to the pixels PX, and the non-display area NDA may include a driving circuit area DRA. For example, the pixel areas PXA where the pixels PX are disposed may be defined in the display area DA, and the driving circuit area DRA where the first driver 120 and/or the data distributor are disposed may be defined in the non-display area NDA.

In an embodiment, a barrier layer BRL may be provided on the substrate SUB. For example, the display panel 110 may further include the barrier layer BRL disposed between the substrate SUB and the panel circuit layer PCL. In another embodiment, the display panel 110 may not include the barrier layer BRL. For example, the panel circuit layer PCL may be disposed directly on the substrate SUB.

The barrier layer BRL may include at least one inorganic insulating layer including an inorganic insulating material (e.g., silicon nitride, silicon oxide, silicon oxynitride, titanium oxide, aluminum oxide, or another inorganic insulating material). The barrier layer BRL may protect the pixels PX from moisture permeating through the substrate SUB that is susceptible to moisture permeation. The material of the barrier layer BRL may be variously changed according to embodiments.

The panel circuit layer PCL may be disposed on a surface of the substrate SUB where the barrier layer BRL is provided. The panel circuit layer PCL may include circuit elements including the pixel transistors Tpx and the driver transistors Tdr, and wires (e.g., signal lines and power lines). In an embodiment, the panel circuit layer PCL may further include additional conductive pattern layers (e.g., bridge pattern layers).

The panel circuit layer PCL may further include insulating layers disposed on the substrate SUB. For example, the panel circuit layer PCL may include a buffer layer BFL (also referred to as “a first insulating layer”), a gate insulating layer GI (also referred to as “a second insulating layer”), an interlayer insulating layer ILD (also referred to as “third insulating layer”), and a passivation layer PSV (also referred to as “fourth insulating layer”) that are sequentially disposed on the substrate SUB along the third direction D3. In an embodiment, the buffer layer BFL, the interlayer insulating layer ILD, and the passivation layer PSV may be entirely (or overall) disposed in the display area DA and the driving circuit area DRA.

In an embodiment, the gate insulating layer GI may be entirely (or overall) or partially disposed in the display area DA, and may be partially disposed in the driving circuit area DRA. For example, the gate insulating layer GI may include the first gate insulating layer GI1 disposed entirely (or overall) in the display area DA as shown in FIG. 6, or first gate insulating layers GI1 (for example, first gate insulating layers GI1 individually patterned to correspond to the respective pixel transistors Tpx) disposed partially in the display area DA as shown in FIG. 7. Further, the gate insulating layer GI may include second gate insulating layers GI2 (for example, second gate insulating layers GI2 individually patterned to correspond to the respective driver transistors Tdr) disposed partially in the driving circuit area DRA as shown in FIGS. 6 and 7.

In an embodiment, the passivation layer PSV may have a multilayer structure including an inorganic layer (for example, an inorganic insulating layer) and an organic layer (for example, an organic insulating layer). For example, the passivation layer PSV may include an inorganic layer IOL and an organic layer ORL sequentially disposed on the interlayer insulating layer ILD.

In an embodiment, the display panel 110 may further include an additional conductive layer and/or an additional passivation layer. For example, the display panel 110 may further include a fourth conductive layer provided on the passivation layer PSV, and an insulating layer that covers the fourth conductive layer. In an embodiment in which the display panel 110 further includes the fourth conductive layer, at least one wiring and/or bridge pattern layer (for example, bridge pattern layer connected between a first source electrode SE1 of the first transistor TFT1 and a first electrode ET1 of the light emitting element ED) or the like may be provided on the fourth conductive layer.

In an embodiment, each of the buffer layer BFL, the gate insulating layer GI, the interlayer insulating layer ILD, and the inorganic layer IOL may include at least one inorganic insulating layer including an inorganic insulating material (e.g., silicon nitride, silicon oxide, silicon oxynitride, titanium oxide, aluminum oxide, or another inorganic insulating material).

The organic layer ORL may include at least one organic insulating layer including an organic insulating material (e.g., acryl resin, epoxy resin, phenolic resin, polyamide resin, polyimide resin, or other organic insulating materials). The surface (for example, the top surface or upper surface) of the organic layer ORL may be substantially flat.

The pixel transistors Tpx may be included in the pixel circuit PC of each pixel PX, and may be positioned in the display arca DA. For example, each pixel transistor Tpx may be disposed in the pixel area PXA in which the corresponding pixel PX is disposed or formed. In FIG. 6, on behalf of the pixel transistors Tpx, any one pixel transistor Tpx (e.g., the first pixel transistor T1 connected to the light emitting element ED of the corresponding pixel PX) is illustrated, and this will be referred to as “a first transistor TFT1.”

The driver transistors Tdr may be included in the driving circuit 121 and/or the data distributor of the first driver 120, and may be disposed in the driving circuit area DRA. In an embodiment, the driving circuit area DRA may be disposed in the non-display area NDA. In FIG. 6, on behalf of the driver transistors Tdr, any one driver transistor Tdr (e.g., any one of the fifth to eighth driver transistors Tdr included in the output unit 540 of the n^{th} stage STn) is illustrated, and this will be referred to as “a second transistor TFT2”).

The first transistor TFT1 may include a first active layer ACT1 (also referred to as “a first active pattern layer”) and a first gate electrode GE1. In an embodiment, the first transistor TFT1 may further include the first bottom gate electrode BG1. The buffer layer BFL may be disposed between the first bottom gate electrode BG1 and the first active layer ACT1. The first gate insulating layer GI1 may be disposed between the first active layer ACT1 and the first gate electrode GE1. In an embodiment, the active layers (for example, the first active layer ACT1) of all the pixel transistors Tpx disposed in the display area DA, or some of the pixel transistors Tpx including the first pixel transistor T1 of FIG. 3 may be entirely (or overall) covered by the first gate insulating layer GI1.

In an embodiment, a first oxide semiconductor layer OS1 may be disposed on the active layers (for example, the respective first active layers ACT1 of the pixel transistors Tpx) of all the pixel transistors Tpx disposed in the display area DA, or some of the pixel transistors Tpx including the first pixel transistor T1 of FIG. 3. For example, the first oxide semiconductor layer OS1 may be disposed between the first active layer ACT1 and the first gate electrode GE1, and the first oxide semiconductor layer OS1 may be disposed on the first gate insulating layer GI1.

In an embodiment, the first transistor TFT1 may further include the first source electrode SE1 and a first drain electrode DE1 connected to different parts of the first active layer ACT1. In another embodiment, the first transistor TFT1 may not include a separate source electrode and/or a separate drain electrode, and a first source region SR1 and/or a first drain region DR1 of the first active layer ACTI may be connected to another circuit element, wire, and/or conductive pattern layer to function as the source electrode and/or the drain electrode of the first transistor TFT1.

The first bottom gate electrode BG1 may be provided or included in a first conductive layer CDL1 on the substrate SUB. In an embodiment, the first conductive layer CDL1 may be disposed between the substrate SUB and the buffer layer BFL. For example, the first conductive layer CDL1 may be disposed on the barrier layer BRL, and may be covered by the buffer layer BFL.

The first bottom gate electrode BG1 may overlap the first active layer ACTI. For example, the first bottom gate electrode BG1 may be disposed under the first active layer ACT1 to overlap at least a first channel region CH1. The first bottom gate electrode BG1 and the first active layer ACT1 may be spaced apart from each other with the buffer layer BFL interposed between the first bottom gate electrode BG1 and the first active layer ACT1. The first bottom gate electrode BG1 may face the first gate electrode GE1 with the first active layer ACTI interposed between the first bottom gate electrode BG1 and the first gate electrode GE1. In an embodiment, in case that the first transistor TFT1 is the first pixel transistor T1 of FIG. 3, the first bottom gate electrode BG1 of the first transistor TFT1 may be connected to the first source electrode SE1, and may be functioned as a back-gate electrode that adjusts the characteristics of the first pixel transistor T1.

The first active layer ACTI may be provided or included in a first semiconductor layer SCL1 on the substrate SUB. In an embodiment, the first semiconductor layer SCL1 may be disposed on the buffer layer BFL, and may be covered by the gate insulating layer GI and the interlayer insulating layer ILD.

The first active layer ACT1 may include the first channel region CHI and the first source region SRI and the first drain region DR1 spaced apart from each other with the first channel region CHI interposed between the first source region SRI and the first drain region DR1. For example, the first source region SR1 and the first drain region DR1 may be disposed at sides (e.g., opposite sides) of the first channel region CH1. The first channel region CHI may be a region that maintains semiconductor characteristics without becoming conductive. The first source region SR1 and the first drain region DR1, which are regions that have become conductive, may have a carrier concentration (for example, electron concentration) higher than that of the first channel region CH1.

The first active layer ACT1 may overlap the first bottom gate electrode BG1 and the first gate electrode GE1. For example, a part of the first active layer ACT1 including the first channel region CHI may overlap the first bottom gate electrode BG1 and the first gate electrode GE1.

In an embodiment, the first active layer ACT1 may include an oxide semiconductor.

For example, the first active layer ACT1 may include at least one of zinc oxide (ZnO), zinc-tin oxide (ZTO), indium-zinc oxide (IZO), indium oxide (InO), titanium oxide (TiO), indium-gallium oxide (IGO), indium-gallium-zinc oxide (IGZO), indium-gallium-tin oxide (IGTO), indium-zinc-tin oxide (IZTO), or indium-tin-gallium-zinc oxide (ITGZO), or other oxide semiconductors. In an embodiment, the first active layer ACT1 may be formed of a high-mobility oxide semiconductor (for example, an oxide semiconductor material with mobility of approximately 30 cm²/Vs or more). For example, the first active layer ACT1 may be formed of indium-tin-gallium-zinc oxide (ITGZO), and may have mobility of approximately 30 cm²/Vs or more.

The first gate insulating layer GI1 (also referred to as “a first gate insulating pattern layer”) may be disposed on the first active layer ACT1. The first gate insulating layer GI1 may be disposed between the first active layer ACT1 and the first gate electrode GE1.

The first gate insulating layer GI1 may entirely (or overall) cover the first active layer ACT1. For example, the first gate insulating layer GI1 may entirely (or overall) cover the first active layer ACT1 except a portion where at least one contact hole for connection with the first source electrode SE1 and/or the first drain electrode DE1 is formed.

In an embodiment, the first gate insulating layer GI1 may be entirely (or overall) disposed in the display area DA as shown in FIG. 6. In another embodiment, the first gate insulating layer GI1 may be formed individually to correspond to a transistor region where at least one first transistor TFT1 is formed as shown in FIG. 7, and thus may be partially disposed in the display area DA. For example, the first gate insulating layer GI1 may have a shape and a size corresponding to those of the first active layer ACT1 as shown in FIG. 7, and may be an island-shaped insulating pattern layer that covers the top and side surfaces (or upper and side surfaces) of the first active layer ACT1.

The first oxide semiconductor layer OS1 (also referred to as “a first oxide semiconductor pattern layer”) may be disposed on the first gate insulating layer GI1. The first oxide semiconductor layer OS1 may be provided or included in the second semiconductor layer SCL2 on the substrate SUB. The first oxide semiconductor layer OS1 may be disposed between the first gate insulating layer GI1 and the first gate electrode GE1. For example, the first oxide semiconductor layer OS1 may be locally disposed under the first gate electrode GE1.

The first oxide semiconductor layer OS1 may include an oxide semiconductor (for example, at least one of the oxide semiconductors such as the material of the first active layer ACT1, or another oxide semiconductor), and may be disposed on the first channel region CH1 of the first active layer ACT1. Since the first oxide semiconductor layer OS1 is disposed on the first active layer ACT1, oxygen may be supplied to the first active layer ACT1 in the manufacturing process of the display panel 110. Accordingly, although the first active layer ACT1 is formed of a high-mobility oxide semiconductor, the mobility (for example, an electron mobility) and/or the carrier concentration of the first active layer ACT1 may be appropriately and/or readily adjusted, and the operating characteristics (for example, operating characteristics suitable for a driving element and/or a switching element of the pixel PX) of the first transistor TFT1 may be appropriately and/or stably ensured.

In an embodiment, the first gate electrode GE1 and the first oxide semiconductor layer OS1 may be simultaneously or sequentially formed (for example, patterned) using one mask, or the first oxide semiconductor layer OS1 may be formed using the first gate electrode GE1 as a mask. Accordingly, the first oxide semiconductor layer OS1 may have a shape and a size corresponding to those of the first gate electrode GE1. For example, the first oxide semiconductor layer OS1 may be disposed on a part (for example, the first channel region CHI under the first gate electrode GE1) of the first active layer ACT1, and may expose another part (for example, the first source region SRI and the first drain region DR1) of the first active layer ACT1.

The first gate electrode GE1 may be disposed on the first oxide semiconductor layer OS1. The first gate electrode GE1 may be provided or included in a second conductive layer CDL2 on the substrate SUB. In an embodiment, the second conductive layer CDL2 may be disposed on the first semiconductor layer SCL1 including the first active layer ACT1, the gate insulating layer GI including the first gate insulating layer GI1, and the second semiconductor layer SCL2 including the first oxide semiconductor layer OS1. The second conductive layer CDL2 may be covered by the interlayer insulating layer ILD.

The first gate electrode GE1 may be disposed on the first active layer ACT1 to overlap the first channel region CH1. The first gate electrode GE1 and the first active layer ACT1 may be separated and/or spaced apart from each other with the first gate insulating layer GI1 and the first oxide semiconductor layer OS1 interposed between the first gate electrode GE1 and the first active layer ACT1.

The first source electrode SE1 and the first drain electrode DE1 may be provided or included in a third conductive layer CDL3 on the substrate SUB. In an embodiment, the third conductive layer CDL3 may be disposed on the interlayer insulating layer ILD that entirely (or overall) covers the buffer layer BFL, the first semiconductor layer SCL1, the gate insulating layer GI, the second semiconductor layer SCL2, and the second conductive layer CDL2. The third conductive layer CDL3 may be covered by the passivation layer PSV.

The first source electrode SE1 may be connected to a part of the first active layer ACT1. For example, the first source electrode SE1 may be connected to the first source region SR1 through at least one contact hole penetrating the first gate insulating layer GI1 and the interlayer insulating layer ILD. In case that the first transistor TFT1 is the first pixel transistor T1 of FIG. 3, the first source electrode SE1 may be further connected to the first bottom gate electrode BG1. For example, the first source electrode SE1 may be connected to the first bottom gate electrode BG1 through at least one contact hole penetrating the buffer layer BFL, the first gate insulating layer GI1, and the interlayer insulating layer ILD.

The first drain electrode DE1 may be connected to another part of the first active layer ACT1. For example, the first drain electrode DE1 may be connected to the first drain region DR1 through at least one contact hole penetrating the first gate insulating layer GI1 and the interlayer insulating layer ILD.

The second transistor TFT2 may include a second active layer ACT2 (also referred to as “a second active pattern layer”) and a second gate electrode GE2. In an embodiment, the second transistor TFT2 may further include the second bottom gate electrode BG2. The buffer layer BFL may be disposed between the second bottom gate electrode BG2 and the second active layer ACT2. The second gate insulating layer GI2 may be disposed between the second active layer ACT2 and the second gate electrode GE2. In an embodiment, the second gate insulating layer GI2 overlapping the second gate electrode GE2 may be locally disposed on the active layers (for example, the respective second active layers ACT2 of the driver transistors Tdr) of all the driver transistors Tdr disposed in the driving circuit area DRA, or some driver transistors Tdr including at least one of the fifth to eighth driver transistors M5 to M8 of FIG. 5, and other portions of the active layer may not be covered by the second gate insulating layer GI2.

In an embodiment, the second oxide semiconductor layer OS2 may be formed on the active layers (for example, the second active layer ACT2) of some or all of the driver transistors Tdr disposed in the driving circuit area DRA. For example, the second oxide semiconductor layer OS2 may be disposed between the second active layer ACT2 and the second gate electrode GE2, and the second oxide semiconductor layer OS2 may be disposed on the second gate insulating layer GI2.

In an embodiment, the second transistor TFT2 may further include the second source electrode SE2 and the second drain electrode DE2 connected to different parts of the second active layer ACT2. In another embodiment, the second transistor TFT2 may not include a separate source electrode and/or a separate drain electrode, and a second source region SR2 and/or a second drain region DR2 of the second active layer ACT2 may be connected to another circuit element, wire, and/or conductive pattern layer to function as the source electrode and/or the drain electrode of the second transistor TFT2.

The second bottom gate electrode BG2 may be provided or included in the first conductive layer CDL1 on the substrate SUB. For example, the second bottom gate electrode BG2 may be provided or included in the first conductive layer CDL1 together with the first bottom gate electrode BG1.

The second bottom gate electrode BG2 may overlap the second active layer ACT2. For example, the second bottom gate electrode BG2 may be disposed under the second active layer ACT2 to overlap at least the second channel region CH2. The second bottom gate electrode BG2 and the second active layer ACT2 may be spaced apart from each other with the buffer layer BFL interposed between the second bottom gate electrode BG2 and the second active layer ACT2. The second bottom gate electrode BG2 may face the second gate electrode GE2 with the second active layer ACT2 interposed between the second bottom gate electrode BG2 and the second gate electrode GE2. In an embodiment, the second bottom gate electrode BG2 may be connected to the second gate electrode GE2, and may be functioned as a back-gate electrode that adjusts the characteristics of the second transistor TFT2.

The second active layer ACT2 may be provided or included in the first semiconductor layer SCL1 on the substrate SUB. In an embodiment, the first active layer ACT1 and the second active layer ACT2 may be provided and/or disposed on the same layer (e.g., buffer layer BFL) on the substrate SUB.

The second active layer ACT2 may include the second channel region CH2 and the second source region SR2 and the second drain region DR2 spaced apart from each other with the second channel region CH2 interposed between the second source region SR2 and the second drain region DR2. For example, the second source region SR2 and the second drain region DR2 may be disposed at sides (e.g., opposite sides) of the second channel region CH2. The second channel region CH2 may be a region that maintains semiconductor characteristics without becoming conductive. The second source region SR2 and the second drain region DR2, which are regions that have become conductive, may have a carrier concentration (for example, electron concentration) higher than that of the second channel region CH2.

The second active layer ACT2 may overlap the second bottom gate electrode BG2 and the second gate electrode GE2. For example, a part of the second active layer ACT2 including the second channel region CH2 may overlap the second bottom gate electrode BG2 and the second gate electrode GE2.

In an embodiment, the second active layer ACT2 may include an oxide semiconductor. For example, the second active layer ACT2 may include the oxide semiconductor above as the material of the first active layer ACT1, or another oxide semiconductor. In an embodiment, the second active layer ACT2 may be formed of a high-mobility oxide semiconductor.

In an embodiment, the first active layer ACT1 and the second active layer ACT2 may include the same oxide semiconductor. For example, the first active layer ACT1 and the second active layer ACT2 may be formed simultaneously on the buffer layer BFL using the same high-mobility oxide semiconductor. Accordingly, the manufacturing process of the display panel 110 may be simplified and/or streamlined, and the manufacturing efficiency may be increased.

In case that the first active layer ACT1 and the second active layer ACT2 are formed of a high-mobility oxide semiconductor, the conductivity of the first source region SR1, the first drain region DR1, the second source region SR2, and the second drain region DR2 may be appropriately ensured without performing an additional doping process or the like. Accordingly, the manufacturing process of the display device 100 may be further simplified and/or streamlined, and the manufacturing efficiency may be increased.

Further, in case that the first active layer ACT1 and the second active layer ACT2 are formed of a high-mobility oxide semiconductor, it is possible to form the first transistor TFT1 and the second transistor TFT2 having a fine size (for example, a size including an active layer with a width and/or a length in a range of approximately several micrometers to several tens of micrometers) and also possible to appropriately ensure the mobility of the first transistor TFT1 and the second transistor TFT2. Accordingly, even in the high-resolution display device 100, it is possible to readily arrange and/or form the pixel transistors Tpx and/or the driver transistors Tdr, and to appropriately ensure device characteristics and/or operating characteristics of the pixel transistors Tpx and/or the driver transistors Tdr. Further, since the first active layer ACT1 and the second active layer ACT2 are formed of a high-mobility oxide semiconductor, the power consumption of the display device 100 may be reduced.

The second gate insulating layer GI2 (also referred to as “a second gate insulating pattern layer”) may be disposed on the second active layer ACT2. The second gate insulating layer GI2 may be disposed between the second active layer ACT2 and the second gate electrode GE2.

The second gate insulating layer GI2 may cover a part (or a portion) of the second active layer ACT2 that overlaps the second gate electrode GE2, and may expose another part (or another portion) of the second active layer ACT2. For example, the second gate insulating layer GI2 may be disposed only on a part of the second active layer ACT2 to cover the second channel region CH2 and expose the second source region SR2 and the second drain region DR2. In an embodiment, the second gate insulating layer GI2 may be an island-shaped insulating pattern layer having a shape and a size corresponding to those of the second gate electrode GE2, and may be individually formed in each transistor region where each driver transistors Tdr is formed.

Since the second gate insulating layer GI2 exposes the second source region SR2 and the second drain region DR2, the second source region SR2 and the second drain region DR2 may become appropriately and/or readily conductive in the manufacturing process of the display panel 110. For example, in the step of forming the second gate insulating layer GI2 to expose the second source region SR2 and the second drain region DR2, a large number of oxygen-vacancies (for example, larger than those in the first source region SR1 and the first drain region DR1) may occur in the second source region SR2 and the second drain region DR2 by an etching gas or the like. Further, by forming the interlayer insulating layer ILD in a state where the second source region SR2 and the second drain region DR2 are exposed, a larger amount of hydrogen may flow into the second source region SR2 and the second drain region DR2. Accordingly, the second transistor TFT2 may have mobility higher than that of the first transistor TFT1, and may have improved switching characteristics. For example, in case that the first transistor TFT1 and the second transistor TFT2 are N-type oxide transistors, the electron mobility of the second transistor TFT2 may be higher than the electron mobility of the first transistor TFT1.

The second oxide semiconductor layer OS2 (also referred to as “a second oxide semiconductor pattern layer”) may be disposed on the second gate insulating layer GI2. The second oxide semiconductor layer OS2 may be provided or included in the second semiconductor layer SCL2 on the substrate SUB. For example, the second oxide semiconductor layer OS2 and the first oxide semiconductor layer OS1 may be provided on the same layer (e.g., gate insulating layer GI) on the substrate SUB.

The second oxide semiconductor layer OS2 may be disposed between the second gate insulating layer GI2 and the second gate electrode GE2. For example, the second oxide semiconductor layer OS2 may be locally disposed under the second gate electrode GE2.

The second oxide semiconductor layer OS2 may include an oxide semiconductor, and may be disposed on the second channel region CH2 of the second active layer ACT2. Since the second oxide semiconductor layer OS2 is disposed on the second active layer ACT2, oxygen may be supplied to the second active layer ACT2 in the manufacturing process of the display panel 110. Accordingly, although the second active layer ACT2 is formed of a high-mobility oxide semiconductor, it is possible to appropriately and/or readily adjust the mobility (for example, the electron mobility) and/or the carrier concentration of the second active layer ACT2, and also possible to appropriately and/or stably ensure the operating characteristics (for example, operating characteristics suitable for a switching element and/or a buffer transistor of the driving circuit 121) of the second transistor TFT2.

In an embodiment, the first oxide semiconductor layer OS1 and the second oxide semiconductor layer OS2 may include the same oxide semiconductor. For example, the first oxide semiconductor layer OS1 and the second oxide semiconductor layer OS2 may be simultaneously formed on the first gate insulating layer GI1 and the second gate insulating layer GI2, respectively, using the same oxide semiconductor.

In an embodiment, the second gate electrode GE2 and the second oxide semiconductor layer OS2 may be simultaneously or sequentially formed (for example, patterned) using one mask, or the second oxide semiconductor layer OS2 may be formed using the second gate electrode GE2 as a mask. Accordingly, the second oxide semiconductor layer OS2 may have a shape and a size corresponding to those of the second gate electrode GE2. For example, the second oxide semiconductor layer OS2 may be disposed on a part (for example, the second channel region CH2 under the second gate electrode GE2) of the second active layer ACT2, and may expose another part (for example, the second source region SR2 and the second drain region DR2) of the second active layer ACT2.

The second gate electrode GE2 may be disposed on the second oxide semiconductor layer OS2. The second gate electrode GE2 may be provided or included in the second conductive layer CDL2 on the substrate SUB. For example, the first gate electrode GE1 and the second gate electrode GE2 may be provided and/or disposed on the same layer on the substrate SUB.

The second gate electrode GE2 may be disposed on the second active layer ACT2 to overlap the second channel region CH2. The second gate electrode GE2 and the second active layer ACT2 may be separated and/or spaced apart from each other with the second gate insulating layer GI2 and the second oxide semiconductor layer OS2 interposed between the second gate electrode GE2 and the second active layer ACT2.

The second source electrode SE2 and the second drain electrode DE2 may be provided or included in the third conductive layer CDL3 on the substrate SUB. For example, the second source electrode SE2, the second drain electrode DE2, the first source electrode SE1, and the first drain electrode DE1 may be disposed on the same layer (e.g., interlayer insulating layer ILD) on the substrate SUB.

The second source electrode SE2 may be connected to a part of the second active layer ACT2. For example, the second source electrode SE2 may be connected to the second source region SR2 through at least one contact hole penetrating the interlayer insulating layer ILD.

The second drain electrode DE2 may be connected to another part of the second active layer ACT2. For example, the second drain electrode DE2 may be connected to the second drain region DR2 through at least one contact hole penetrating the interlayer insulating layer ILD.

The transistors TFT, including the first transistors TFT1 of the pixels PX and the second transistors TFT2 of the driving circuit 121, may be covered by the passivation layer PSV.

The respective electrodes, conductive pattern layers, and/or wires provided or included in the conductive layers of the panel circuit layer PCL may include at least one conductive material, and may each have a single layer structure or a multilayer structure. For example, the electrodes, the conductive pattern layers, and/or the wires provided or included in each of the first conductive layer CDL1, the second conductive layer CDL2, and the third conductive layer CDL3 may include at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg), or another metal, an alloy thereof, or another conductive material, and may each have a single layer structure or a multilayer structure. In an embodiment, the electrodes, the conductive pattern layers, and/or the wires disposed or included in the same conductive layer may be simultaneously formed of the same conductive material.

The light emitting element layer LEL may be disposed on the panel circuit layer PCL, and may be disposed in the display area DA. For example, the light emitting element layer LEL may be disposed on the panel circuit layer PCL in the display area DA.

The light emitting element layer LEL may include the light emitting elements ED of the pixels PX. For example, the light emitting element layer LEL may include a pixel defining layer PDL (also referred to as “bank”) that partitions the emission areas of the pixels PX and the light emitting element ED disposed in each emission area. In an embodiment, the light emitting clement layer LEL may further include a spacer SPC disposed on a part of the pixel defining layer PDL.

Each light emitting element ED may include the first electrode ET1 connected to at least one pixel transistor Tpx (for example, the first pixel transistor T1) included in the corresponding pixel PX, and a light emitting layer EML and a second electrode ET2 that are sequentially disposed on the first electrode ET1. In an embodiment, the light emitting element ED may further include a first intermediate layer (e.g., hole layer including a hole transport layer) interposed between the first electrode ET1 and the light emitting layer EML, and a second intermediate layer (e.g., an electron layer including an electron transport layer) interposed between the light emitting layer EML and the second electrode ET2.

The first electrode ET1 of the light emitting element ED may be disposed on the panel circuit layer PCL to correspond to each emission area. The first electrode ET1 may include a conductive material. In an embodiment, the first electrode ET1 may include a metallic material having high reflectivity. For example, the first electrode ET1 may have a single-layer structure of molybdenum (Mo), titanium (Ti), copper (Cu) or aluminum (Al), or may have a multi-layer structure (e.g., ITO/Mg, ITO/MgF, ITO/Ag, and ITO/Ag/ITO) including indium-tin-oxide (ITO), indium-zinc-oxide (IZO), zinc oxide (ZnO), indium oxide (In₂O₃) and silver (Ag), magnesium (Mg), aluminum (Al), platinum (Pt), lead (Pb), gold (Au), or nickel (Ni).

The light emitting layer EML of the light emitting element ED may include a high molecular material or a low molecular material. Light emitted from the light emitting layer EML may be used for image display.

The second electrode ET2 of the light emitting element ED may include a conductive material. In an embodiment, the second electrode ET2 may be a common layer formed across the entire display area DA to cover the light emitting layer EML and the pixel defining layer PDL. In an embodiment, the second electrode ET2 may be formed of a transparent conductive material (TCO) such as ITO, IZO, ZnO, or ITZO capable of transmitting light or a semi-transmissive conductive material such as magnesium (Mg), silver (Ag), or an alloy of magnesium (Mg) and silver (Ag).

The pixel defining layer PDL may have an opening corresponding to each emission area and may surround the emission area. For example, the pixel defining layer PDL may be formed to cover an edge portion of the first electrode ET1 of the light emitting element ED and may include an opening exposing the remaining portion of the first electrode ET1. A region where the exposed first electrode ET1 and the light emitting layer EML overlap may be defined as the emission area of each pixel PX.

In an embodiment, the pixel defining layer PDL may include at least one organic insulating layer including an organic insulating material. For example, the pixel defining layer PDL may include acrylic resin, epoxy resin, phenolic resin, polyamide resin, polyimide resin, unsaturated polyester resin, polyphenylene ether resin, polyphenylenesulfide resin and benzocyclobutene (BCB) or other organic insulating materials.

The spacer SPC may be disposed on a part of the pixel defining layer PDL. The spacer SPC may include at least one organic insulating layer including an organic insulating material. The spacer SPC and the pixel defining layer PDL may include the same material, or may include a different material from the pixel defining layer PDL. In an embodiment, the pixel defining layer PDL and the spacer SPC may be sequentially formed by separate mask processes. In another embodiment, the pixel defining layer PDL and the spacer SPC may be an integrated pattern layer formed simultaneously using a halftone mask.

The encapsulation layer ENL may be disposed on the light emitting element layer LEL. The encapsulation layer ENL may cover the light emitting element layer LEL in the display arca DA and may extend to the non-display area NDA to be in contact with the panel circuit layer PCL. For example, the encapsulation layer ENL may be disposed in the display area DA to cover the light emitting element layer LEL, and the end portion of the encapsulation layer ENL may be disposed in a portion of the non-display area NDA adjacent to the display arca DA. The encapsulation layer ENL may block the permeation of oxygen or moisture into the light emitting element layer LEL, and may reduce electrical and/or physical impacts to the panel circuit layer PCL and the light emitting element layer LEL.

In an embodiment, the encapsulation layer ENL may include a first encapsulation layer ENL1, a second encapsulation layer ENL2, and a third encapsulation layer ENL3 sequentially disposed on the light emitting element layer LEL. Each of the first encapsulation layer ENL1 and the third encapsulation layer ENL3 may be an inorganic encapsulation layer including an inorganic material. The second encapsulation layer ENL2 may be an organic encapsulation layer including an organic material.

In accordance with the above-described embodiments, the first gate insulating layer GI1 may be disposed on the first active layer ACT1 of the first transistor TFT1 to entirely (or overall) cover the first active layer ACT1. For example, the first gate insulating layer GI1 may entirely (or overall) cover the first active layer ACT1 except a portion where at least one contact hole is formed in the first gate insulating layer GI1 and the interlayer insulating layer ILD for connection with the first source electrode SE1 and/or the first drain electrode DE1.

Accordingly, the threshold voltage and the driving range of the first transistor TFT1 may be appropriately ensured, and the operating characteristics of the first transistor TFT1 may be stabilized. For example, in the manufacturing process of the display panel 110, in a state where the first active layer ACT1 is entirely (or overall) covered by the gate insulating layer GI (or the first gate insulating layer GI1), a patterning process (for example, an etching process) of the gate insulating layer GI, a forming process (for example, a deposition process) of the interlayer insulating layer ILD, and/or a heat treatment process may be performed. Accordingly, the threshold voltage shift (for example, negative shift) of the first transistor TFT1 may be prevented or reduced, and the driving range of the first transistor TFT1 may be appropriately and/or stably ensured. Further, compared to the case where the gate insulating layer GI is etched to expose the first source region SR1 and/or the first drain region DR1, the range (for example, the length and/or the area of the portion where the first source region SR1 and/or the first drain region DR1 are formed in the first active layer ACT1) where the first source region SRI and/or the first drain region DR1 expand may be relatively small. Accordingly, the first channel region CH1 having a sufficient length may be formed under the first gate electrode GE1, and the parasitic capacitance of the first transistor TFT1 may be reduced. Accordingly, in case that the first active layer ACT1 is formed of a high-mobility oxide semiconductor, the effective channel length may be appropriately ensured, and the operating characteristics of the first transistor TFT1 may be stabilized.

For example, the second gate insulating layer GI2 that locally covers a part of the second active layer ACT2 that overlaps the second gate electrode GE2 and exposes another part of the second active layer ACT2 may be disposed on the second active layer ACT2 of the second transistor TFT2. Accordingly, in the process of forming the second gate insulating layer GI2 by patterning the gate insulating layer GI, mainly at a part (for example, the second source region SR2 and the second drain region DR2) that does not overlap the second gate electrode GE2, a large number of oxygen vacancies may occur in the oxide semiconductor forming the second active layer ACT2 by an etching gas or the like. The oxygen vacancy may partially diffuse to a part of the second active layer ACT2 that overlaps the second gate electrode GE2. Further, in case that the process of forming the interlayer insulating layer ILD and/or the heat treatment process are performed in a state where the second source region SR2 and the second drain region DR2 are not covered by the second gate insulating layer GI2, the amount of hydrogen flowing into the second source region SR2 and the second drain region DR2 may increase. Accordingly, the second source region SR2 and the second drain region DR2 may have higher conductivity (for, higher mobility and/or carrier concentration). Further, in case that each of the second source region SR2 and the second drain region DR2 expands to a region that partially overlaps the second gate electrode GE2, a larger parasitic capacitance may be formed between the second source region SR2 and the second drain region DR2 and the second gate electrode GE2. Accordingly, the on-current (for example, a drain-source current in a turn-on state) of the second transistor TFT2 may increase, so that the output characteristics (for example, the switching characteristics and/or the response speed) of the second transistor TFT2 may be improved. Since the output characteristics of the second transistor TFT2 are improved, the output characteristics of the driving circuit 121 and the like may be improved, thereby stably driving the pixels PX.

In accordance with the above-described embodiments, the gate insulating layer GI may be disposed in different shapes on an active layer (e.g., first and second active layers ACT1 and ACT2) of each transistor TFT according to the characteristics required for each transistor TFT. Accordingly, the characteristics of each transistor TFT may be appropriately adjusted and/or optimized.

For example, at least one pixel transistor Tpx that requires more uniform and stable characteristics may be formed of the first transistor TFT1 including the first active layer ACT1 that is entirely (or overall) covered by the first gate insulating layer GI1. Accordingly, the variation in the characteristics of the first transistor TFT1 may be prevented, reduced, or minimized, and stable operating characteristics may be ensured. Accordingly, it is possible to prevent, reduce, or minimize blurring of the image due to the luminance variation of the pixels PX, and to improve the image quality of the display device 100.

For example, at least one driver transistor Tdr that requires a higher on-current to stably drive the pixels PX may be formed of the second transistor TFT2 including the second active layer ACT2 where only a partial region including the lower side of the second gate electrode GE2 is covered by the second gate insulating layer GI2. Accordingly, the mobility and/or the on-current of the second transistor TFT2 may be appropriately and/or readily increased, and the output characteristics (for example, the switching characteristics and/or the response speed) of the second transistor TFT2 may be improved. Further, since the output characteristics of the second transistor TFT2 are improved, the output characteristics of the driving circuit 121 and the like may be improved, thereby stably driving the pixels PX.

In an embodiment, among the pixel transistors Tpx disposed in each pixel PX, the pixel transistor Tpx that requires a high-speed switching operation may be formed in a structure different from that of the first transistor TFT1. For example, at least one switching element (for example, at least one of the second to fifth pixel transistors T2 to T5 in FIG. 3) provided to each pixel PX may be formed in a structure in which the active layer is partially covered by the gate insulating layer GI, similarly to the second transistor TFT2. For example, all the pixel transistors Tpx disposed in each pixel PX may be formed in the same structure as that of the first transistor TFT1, or some of the pixel transistors Tpx may be formed in the same structure as that of the first transistor TFT1, and some others of the pixel transistors Tpx may be formed in the same structure as that of the second transistor TFT2.

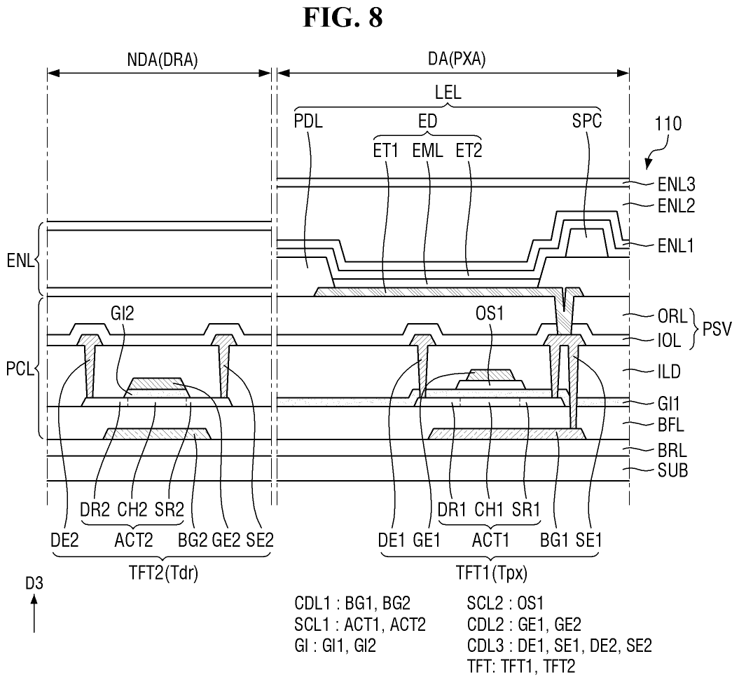

FIG. 8 is a schematic cross-sectional view illustrating the display panel 110 according to an embodiment. For example, FIG. 8 shows a part of the display area DA and a part of the non-display area NDA of the display panel 110, and shows an embodiment different from the embodiment of FIG. 6 in relation to the second oxide semiconductor layer OS2.

Referring to FIG. 8 in addition to FIGS. 1 to 7, the second oxide semiconductor layer OS2 of FIG. 6 may not be provided on the second active layer ACT2 of the second transistor TFT2. For example, the second gate electrode GE2 of the second transistor TFT2 may be disposed (e.g., directly disposed) on the second gate insulating layer GI2, and an oxide semiconductor layer may not be provided between the second gate electrode GE2 and the second active layer ACT2.

In an embodiment, the first oxide semiconductor layer OS1 may be selectively formed only on at least one pixel transistor Tpx (for example, the first transistor TFT1) that requires more uniform and stable characteristics. In an embodiment, an oxide semiconductor layer may not be formed on the active layers of other transistors (for example, the second transistor TFT2) of the display panel 110 as well as the driver transistors Tdr, so that the switching characteristics may be improved.

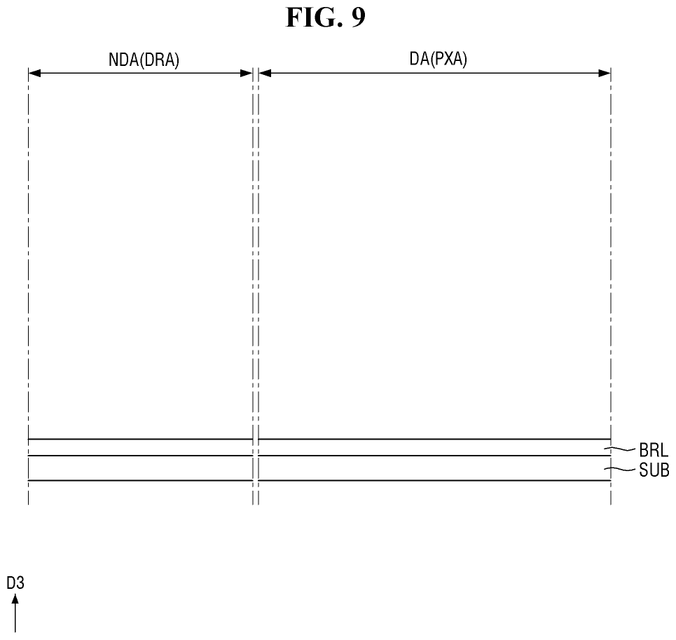

FIGS. 9, 10, 11, 12, 13, 14, 15, and 16 are schematic cross-sectional views showing a method of manufacturing the display device 100 according to an embodiment. For example, FIGS. 9, 10, 11, 12, 13, 14, 15, and 16 sequentially show steps of forming the first and second transistors TFT1 and TFT2 on the substrate SUB among the steps of manufacturing the display panel 110 of FIG. 6.

Referring to FIG. 9 in addition to FIGS. 1 to 7, the substrate SUB including the display area DA and the non-display area NDA may be prepared. In an embodiment, the display arca DA defined on the substrate SUB may include the pixel area PXA, and the non-display area NDA may include the driving circuit area DRA.

In an embodiment, the barrier layer BRL may be formed on the substrate SUB. The barrier layer BRL may be formed in the display area DA and the non-display area NDA. The barrier layer BRL may be formed by an insulating film forming process (for example, a deposition process) using at least one insulating material (for example, an inorganic insulating material) above.

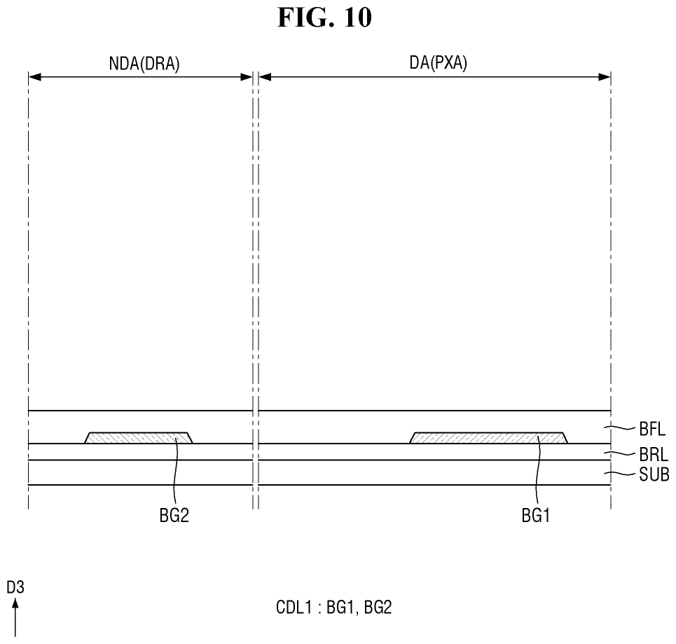

Referring to FIG. 10 in addition to FIGS. 1 to 9, the first conductive layer CDLI including the first bottom gate electrode BG1 and a second bottom gate electrode BG2 may be formed on the substrate SUB (for example, on the barrier layer BRL). For example, on the substrate SUB, the first bottom gate electrode BG1 may be formed in each pixel area PXA of the display area DA, and the second bottom gate electrode BG2 may be formed in the driving circuit area DRA. The first bottom gate electrode BG1 and the second bottom gate electrode BG2 may be formed by a film forming process (for example, a deposition process) of a conductive layer using at least one conductive material above and a patterning process (for example, an etching process using a mask) of the conductive layer.

Thereafter, the buffer layer BFL that covers the first conductive layer CDLI may be formed on the substrate SUB. The buffer layer BFL may be formed by a film forming process of an insulating layer using at least one insulating material (for example, an inorganic insulating material) above.

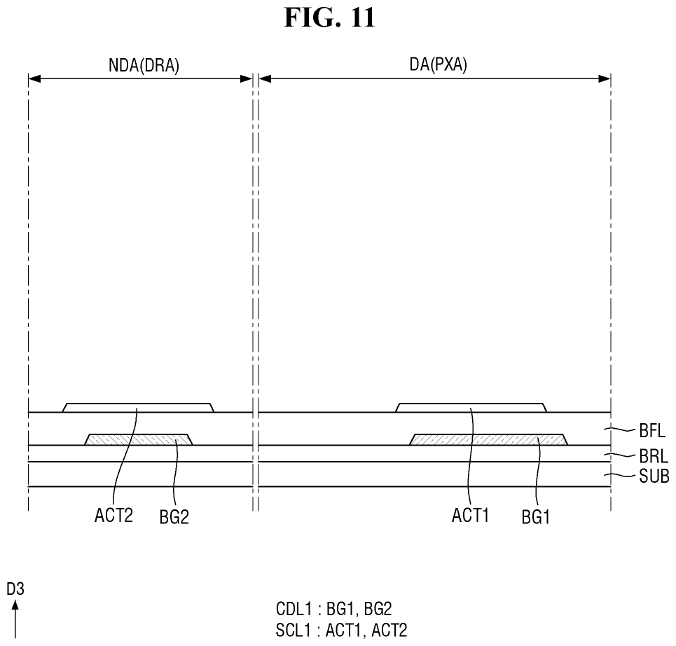

Referring to FIG. 11 in addition to FIGS. 1 to 10, the first semiconductor layer SCL1 including the first active layer ACT1 and the second active layer ACT2 may be formed on the substrate SUB (for example, on the buffer layer BFL). For example, on the substrate SUB, the first active layer ACT1 may be formed in each pixel area PXA of the display area DA, and the second active layer ACT2 may be formed in the driving circuit area DRA. The first active layer ACT1 may be formed to overlap the first bottom gate electrode BG1, and the second active layer ACT2 may be formed to overlap the second bottom gate electrode BG2.

In an embodiment, the first active layer ACT1 and the second active layer ACT2 may be formed simultaneously of the same oxide semiconductor. For example, the first active layer ACT1 and the second active layer ACT2 may be formed in the display area DA and the driving circuit area DRA, respectively, by a film forming process of a semiconductor layer using at least one oxide semiconductor above and a patterning process.

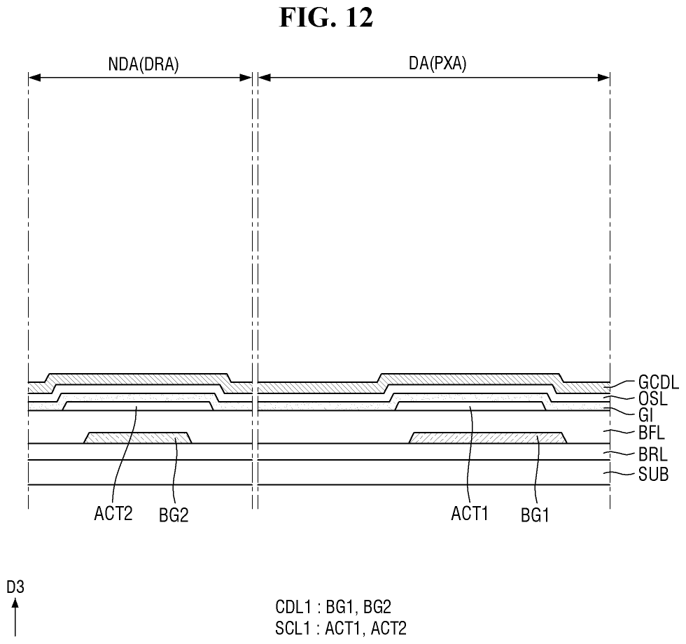

Referring to FIG. 12 in addition to FIGS. 1 to 11, the gate insulating layer GI, the oxide semiconductor layer OSL, and a conductive layer GCDL may be sequentially formed on the substrate SUB on which the first semiconductor layer SCL1 and the like are disposed.

The gate insulating layer GI may be formed to cover the first semiconductor layer SCL1 including the first active layer ACT1 and the second active layer ACT2. The gate insulating layer GI may be formed by a film forming process of an insulating layer using at least one insulating material (for example, an inorganic insulating material) above.

The oxide semiconductor layer OSL may be formed to cover the gate insulating layer GI. The oxide semiconductor layer OSL may be formed by a film forming process of a semiconductor layer using at least one oxide semiconductor above.

The conductive layer GCDL may be formed to cover the oxide semiconductor layer OSL. The conductive layer GCDL may be formed by the film forming process of the conductive layer using at least one conductive material above.

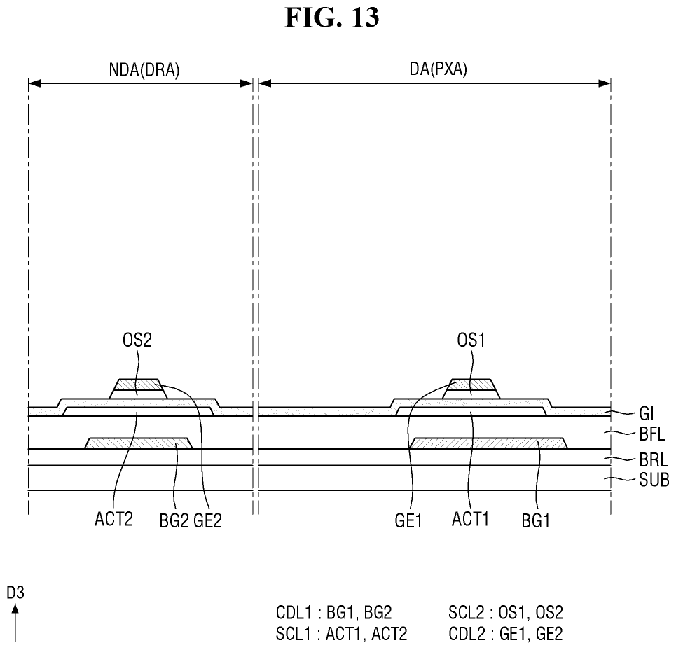

Referring to FIG. 13 in addition to FIGS. 1 to 12, the second conductive layer CDL2 including the first gate electrode GE1 and the second gate electrode GE2 may be formed on the oxide semiconductor layer OSL (or the first oxide semiconductor layer OS1 and the second oxide semiconductor layer OS2 formed by the oxide semiconductor layer OSL). The first gate electrode GE1 and the second gate electrode GE2 may be formed by the patterning process of the conductive layer GCDL including an etching process. The first gate electrode GE1 may be formed to overlap a part of the first active layer ACT1, and the second gate electrode GE2 may be formed to overlap a part of the second active layer ACT2.

In an embodiment, the first oxide semiconductor layer OS1 and the second oxide semiconductor layer OS2 may be formed by etching the oxide semiconductor layer OSL using a mask used for forming the first gate electrode GE1 and the second gate electrode GE2, or using the first gate electrode GE1 and the second gate electrode GE2 as a mask. The first oxide semiconductor layer OS1 may be formed under the first gate electrode GE1, and may have a shape corresponding to that of the first gate electrode GE1. For example, the first oxide semiconductor layer OS1 may have a shape and a size corresponding to the shape and the size of the first gate electrode GE1. The second oxide semiconductor layer OS2 may be formed under the second gate electrode GE2, and may have a shape corresponding to that of the second gate electrode GE2. For example, the second oxide semiconductor layer OS2 may have a shape and a size corresponding to the shape and the size of the second gate electrode GE2.

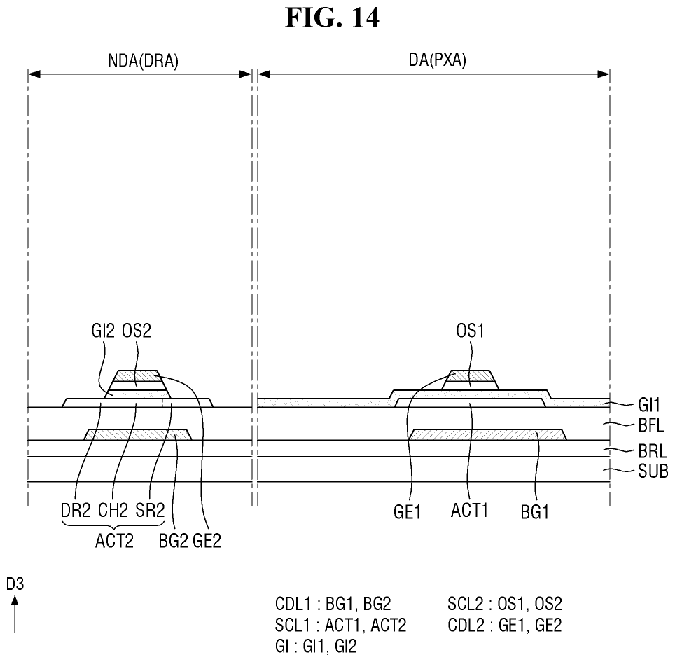

Referring to FIG. 14 in addition to FIGS. 1 to 13, the gate insulating layer GI may be patterned to form the first gate insulating layer GI1 and the second gate insulating layer GI2 by etching the gate insulating layer GI. The first gate insulating layer GI1 may be formed to entirely (or overall) cover at least the first active layer ACT1. In an embodiment, the first gate insulating layer GI1 may be formed entirely (or overall) in the display area DA, and the second gate insulating layer GI2 separated from the first gate insulating layer GI1 may be formed by etching the first gate insulating layer GI1 in the driving circuit area DRA. The second gate insulating layer GI2 may be formed to partially cover the second active layer ACT2, and may be formed individually in each second transistor region including each second active layer ACT2.

In the process of etching the gate insulating layer GI, the properties of the second active layer ACT2 may be changed so that parts of the second active layer ACT2 have different characteristics. Accordingly, the second active layer ACT2 may be divided into regions having different characteristics.

For example, mainly at a part that does not overlap the second gate electrode GE2, oxygen vacancy may occur in the oxide semiconductor forming the second active layer ACT2 by an etching gas or the like. Accordingly, the second active layer ACT2 may be divided into regions (for example, the second channel region CH2, the second source region SR2, and the second drain region DR2) having different characteristics. In an embodiment, oxygen vacancy may occur mainly at a part (for example, the second source region SR2 and the second drain region DR2) of the second active layer ACT2 that does not overlap the second gate electrode GE2, and may diffuse to a part of the region that overlaps the second gate electrode GE2.

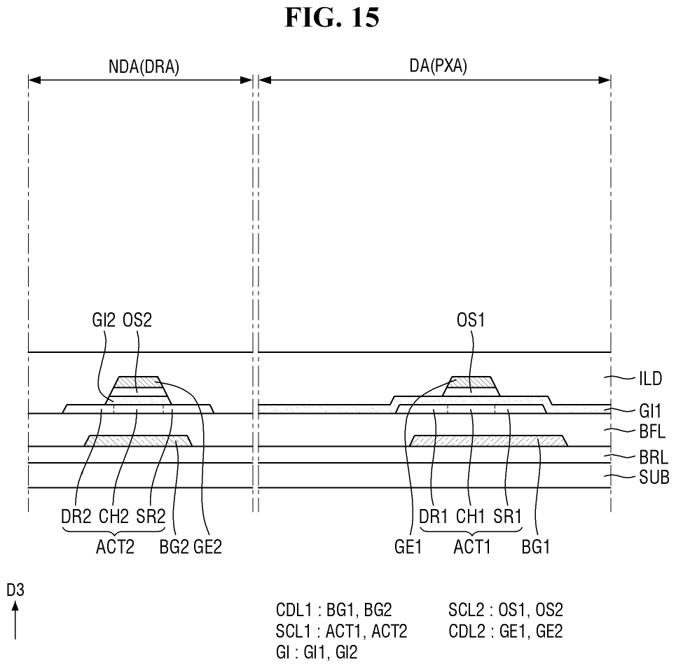

Referring to FIG. 15 in addition to FIGS. 1 to 14, the interlayer insulating layer ILD may be formed on the substrate SUB to cover the buffer layer BFL, the first semiconductor layer SCL1 including the first and second active layers ACT1 and ACT2, the gate insulating layer GI including the first and second gate insulating layers GI1 and GI2, the second semiconductor layer SCL2 including the first and second oxide semiconductor layers OS1 and OS2, and the second conductive layer CDL2 including the first and second gate electrodes GE1 and GE2. For example, the interlayer insulating layer ILD may be formed entirely (or overall) in the display area DA and the non-display area NDA (for example, the driving circuit arca DRA). The interlayer insulating layer ILD may be formed by a film forming process of an insulating layer using at least one insulating material (for example, an inorganic insulating material) above.

In the process of forming the interlayer insulating layer ILD, hydrogen may flow into the first active layer ACT1 and the second active layer ACT2. In an embodiment, a heat treatment process (for example, annealing) may be additionally performed on the first active layer ACT1 and the second active layer ACT2 before or after the formation of the interlayer insulating layer ILD. Even in the heat treatment process, hydrogen may flow into the first active layer ACT1 and the second active layer ACT2.

Since hydrogen flows into the first active layer ACT1 and the second active layer ACT2, a part of the first active layer ACT1 and a part of the second active layer ACT2 may become conductive (for example, conductive to N-type). Accordingly, the first active layer ACT1 may be divided into the first source region SRI and the first drain region DR1 that have conductivity, and the first channel region CHI that maintains semiconductor characteristics.

The second source region SR2 and the second drain region DR2 where a large number of oxygen vacancies have occurred in the process of etching the gate insulating layer GI may become conductive to have conductivity higher than those of the first source region SRI and the first drain region DR1 due to inflow of hydrogen in subsequent processes including the process of forming the interlayer insulating layer ILD.

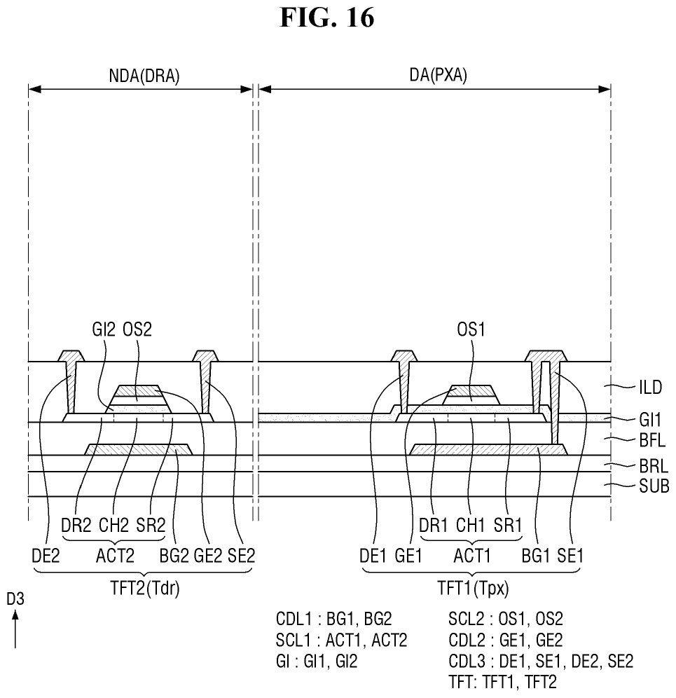

Referring to FIG. 16 in addition to FIGS. 1 to 15, the third conductive layer CDL3 including the first source electrode SE1, the first drain electrode DE1, the second source electrode SE2, and the second drain electrode DE2 may be formed on the interlayer insulating layer ILD. In an embodiment, at least one of the first source region SR1, the first drain region DR1, the second source region SR2, or the second drain region DR2 may replace at least one of the first source electrode SE1, the first drain electrode DE1, the second source electrode SE2, or the second drain electrode DE2, at least one of the first source electrode SE1, the first drain electrode DE1, the second source electrode SE2, or the second drain electrode DE2 may not be formed.

The first source electrode SE1 and the first drain electrode DE1 may be formed to be connected to different parts of the first active layer ACT1. For example, the first source electrode SE may be connected to the first source region SR1, and the first drain electrode DE1 may be connected to the first drain region DR1. The second source electrode SE2 and the second drain electrode DE2 may be formed to be connected to different parts of the second active layer ACT2. For example, the second source electrode SE2 may be connected to the second source region SR2, and the second drain electrode DE2 may be connected to the second drain region DR2. For example, contact holes may be formed in the interlayer insulating layer ILD.

By the above-described process, transistors TFT including the first transistor TFT1 and the second transistor TFT2 may be formed in the display area DA and the driving circuit arca DRA. In an embodiment, elements provided or included in the same conductive layer or the same semiconductor layer in the display panel 110 may be formed simultaneously.

After the transistors TFT are formed, a process of forming the passivation layer PSV shown in FIG. 6 or the like may be performed. The passivation layer PSV may cover the transistors TFT. Accordingly, the panel circuit layer PCL of the display panel 110 may be formed.

In an embodiment, in case that the display panel 110 includes the light emitting element layer LEL and the encapsulation layer ENL disposed on the panel circuit layer PCL, the light emitting element layer LEL and the encapsulation layer ENL may be sequentially formed on the panel circuit layer PCL. The display panel 110 and the display device 100 including the same according to embodiments may be manufactured by the above-described processes.

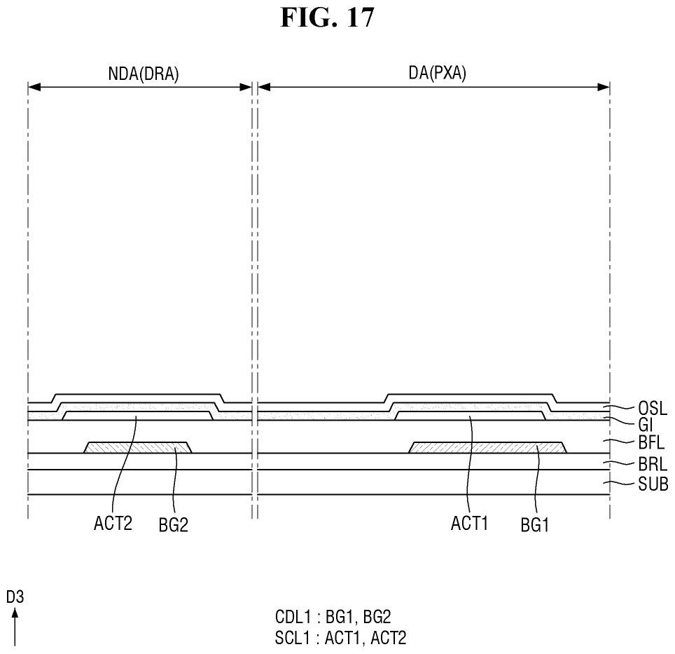

FIGS. 17 to 19 are schematic cross-sectional views showing a method of manufacturing the display device 100 according to an embodiment. For example, FIGS. 17 to 19 sequentially show steps of forming the second semiconductor layer SCL2 and the second conductive layer CDL2 among the steps of manufacturing the display panel 110 of FIG. 8.

Referring to FIG. 17 in addition to FIGS. 1 to 16, the gate insulating layer GI and the oxide semiconductor layer OSL may be sequentially formed on the substrate SUB on which the first conductive layer CDL1 including the first and second bottom gate electrodes BG1 an dBG2 and the first semiconductor layer SCL1 including the first and second active layers ACT1 and ACT2 are disposed. The step of forming the gate insulating layer GI and the step of forming the oxide semiconductor layer OSL may be substantially the same or similar to those in the embodiment described with reference to FIG. 12.

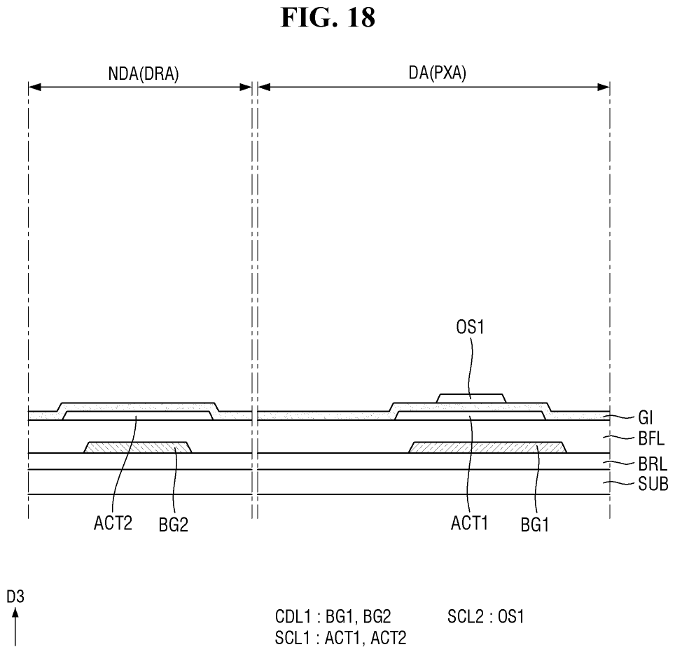

Referring to FIG. 18 in addition to FIGS. 1 to 17, by patterning the oxide semiconductor layer OSL by an etching process using a mask, the first oxide semiconductor layer OS1 may be formed on a part of the first active layer ACT1. In an embodiment, the oxide semiconductor layer may not be formed on the second active layer ACT2.

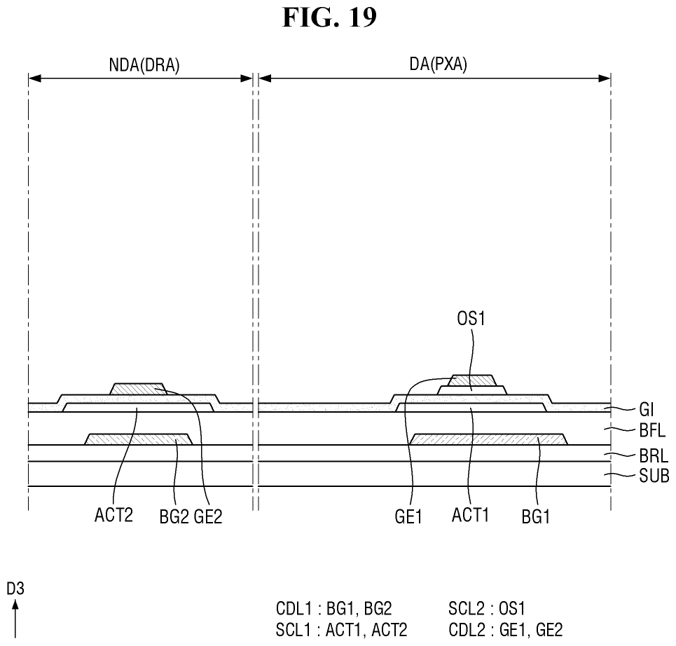

Referring to FIG. 19 in addition to FIGS. 1 to 18, the second conductive layer CDL2 including the first gate electrode GE1 and the second gate electrode GE2 may be formed on the substrate SUB on which the gate insulating layer GE1 and the second gate electrode GE2 may be formed by a film forming process of a conductive layer using at least one conductive material above and a patterning process of the conductive layer.

Thereafter, the patterning process of the gate insulating layer GI, the forming process of the interlayer insulating layer ILD, and the forming process of the third conductive layer CDL3 described with reference to FIGS. 14 to 16 may be performed. Accordingly, the transistors TFT including the first transistor TFT1 and the second transistor TFT2 may be formed in the display area DA and the driving circuit arca DRA.

Thereafter, a process of forming the passivation layer PSV, a process of forming the light emitting element layer LEL, and a process of forming the encapsulation layer ENL may be performed. Accordingly, the display panel 110 and the display device 100 including the same according to the embodiment of FIG. 8 may be manufactured.

In accordance with the display device 100 and the method of manufacturing the same according to the above-described embodiments, the first transistor TFT1 disposed in the display area DA and the second transistor TFT2 disposed in the driving circuit area DRA may be formed in different structures according to the operating characteristics required for each transistor TFT. For example, the first gate insulating layer GI1 may be disposed on the first active layer ACT1 of the first transistor TFT1 to entirely (or overall) cover the first active layer ACT1, and the second gate insulating layer GI2 may be disposed on the second active layer ACT2 of the second transistor TFT2 to partially cover the second active layer ACT2. In accordance with embodiments, the operating characteristics of the first transistor TFT1 and the second transistor TFT2 may be differentiated and/or optimized.

For example, by covering the entire first active layer ACT1 by the first gate insulating layer GI1, the threshold voltage and the driving range of the first transistor TFT1 may be appropriately ensured, and the operating characteristics of the first transistor TFT1 may be stabilized. In some embodiments, the first transistor TFT1 may be the pixel transistor Tpx provided to the pixel PX, and the image quality of the display device 100 may be improved by stabilizing the operating characteristics of the first transistor TFT1.

In case of the second active layer ACT2, by covering only a part of the second active layer ACT2 that overlaps the second gate electrode GE2 by the second gate insulating layer GI2, the on-current of the second transistor TFT2 may be increased, and the output characteristics may be improved. In some embodiments, the second transistor TFT2 may be the driver transistor Tdr provided to the driving circuit 121 or the like, and the output characteristics of the second transistor TFT2 may be improved to improve the output characteristics of the driving circuit 121, and to stably drive the pixels PX.

Further, in accordance with the display device 100 and the method of manufacturing the same, the first oxide semiconductor layer OSI may be disposed between the first gate insulating layer GI1 on the first active layer ACT1 and the first gate electrode GE1. Accordingly, the operating characteristics of the first transistor TFT1 may be stably ensured.

In concluding the detailed description, those skilled in the art will appreciate that many variations and modifications can be made to the embodiments without substantially departing from the principles of the invention. Therefore, the disclosed embodiments are used in a generic and descriptive sense only and not for purposes of limitation.

What is claimed is:

1. A display device comprising:
a substrate comprising a display area and a driving circuit area;
a first transistor disposed in the display area, and comprising:
a first active layer disposed on the substrate, and
a first gate electrode disposed on the first active layer;
a first gate insulating layer disposed between the first active layer and the first gate electrode, and entirely covering the first active layer;
a second transistor disposed in the driving circuit area, and comprising:
a second active layer disposed on the substrate, and
a second gate electrode disposed on the second active layer;
a second gate insulating layer disposed between the second active layer and the second gate electrode, covering a part of the second active layer overlapping the second gate electrode, and exposing another part of the second active layer; and
a first oxide semiconductor layer disposed between the first gate insulating layer and the first gate electrode.

2. The display device of claim 1, further comprising:
a second oxide semiconductor layer disposed between the second gate insulating layer and the second gate electrode.

3. The display device of claim 2, wherein the first oxide semiconductor layer and the second oxide semiconductor layer include a same oxide semiconductor.

4. The display device of claim 1, wherein the second gate electrode is directly disposed on the second gate insulating layer.

5. The display device of claim 1, wherein the first gate insulating layer is entirely disposed in the display area.

6. The display device of claim 1, wherein the first gate insulating layer has a shape and a size corresponding to those of the first active layer, and is an island-shaped insulating pattern layer covering upper and side surfaces of the first active layer.

7. The display device of claim 1, wherein the second gate insulating layer is an island-shaped insulating pattern layer having a shape and a size corresponding to those of the second gate electrode.

8. The display device of claim 1, wherein the first active layer and the second active layer are disposed on a same layer on the substrate, and include a same oxide semiconductor.

9. The display device of claim 1, wherein
the first transistor and the second transistor are N-type oxide transistors, and
an electron mobility of the second transistor is higher than an electron mobility of the first transistor.

10. The display device of claim 1, further comprising:
an interlayer insulating layer entirely covering the first and second active layers, the first and second gate insulating layers, the first oxide semiconductor layer, and the first and second gate electrodes.

11. The display device of claim 10, wherein the first transistor further comprises at least one of a first source electrode and a first drain electrode which are disposed on the interlayer insulating layer and connected to different parts of the first active layer.

12. The display device of claim 11, further comprising:
a buffer layer disposed between the substrate and a semiconductor layer comprising the first active layer and the second active layer,
wherein the first transistor further comprises a first bottom gate electrode disposed between the substrate and the buffer layer and overlapping the first gate electrode with the first active layer disposed between the first bottom gate electrode and the first gate electrode.

13. The display device of claim 12, wherein the first bottom gate electrode is connected to the first source electrode.

14. The display device of claim 10, wherein the second transistor further comprises at least one of a second source electrode and a second drain electrode which are disposed on the interlayer insulating layer and connected to different parts of the second active layer.

15. The display device of claim 1, further comprising:
a buffer layer disposed between the substrate and a semiconductor layer comprising the first active layer and the second active layer,
wherein the second transistor further comprises a second bottom gate electrode disposed between the substrate and the buffer layer and overlapping the second gate electrode with the second active layer disposed between the second bottom gate electrode and the second gate electrode.

16. The display device of claim 15, wherein the second bottom gate electrode is connected to the second gate electrode.

17. The display device of claim 1, further comprising:
a pixel disposed in the display area, and comprising the first transistor; and
a driving circuit disposed in the driving circuit area, and comprising the second transistor.

18. A method of manufacturing a display device, the method comprising:
preparing a substrate comprising a display area and a driving circuit area;
forming a first active layer and a second active layer in the display area and the driving circuit area, respectively, on the substrate;
sequentially forming a gate insulating layer covering the first active layer and the second active layer and an oxide semiconductor layer covering the gate insulating layer on the substrate;
forming a first gate electrode overlapping a part of the first active layer and a second gate electrode overlapping a part of the second active layer, on the oxide semiconductor layer;
patterning the gate insulating layer into a first gate insulating layer which entirely covers the first active layer and a second gate insulating layer which partially covers the second active layer, by etching the gate insulating layer; and
forming an interlayer insulating layer covering the first active layer, the second active layer, the first gate insulating layer, the second gate insulating layer, the first gate electrode, and the second gate electrode, in the display area and the driving circuit area.

19. The method of claim 18, further comprising:
before patterning the gate insulating layer into the first gate insulating layer and the second gate insulating layer, forming a first oxide semiconductor layer having a shape and a size corresponding to those of the first gate electrode under the first gate electrode by etching the oxide semiconductor layer.

20. The method of claim 18, further comprising:
before forming the first gate electrode and the second gate electrode, forming a first oxide semiconductor layer on a part of the first active layer by etching the oxide semiconductor layer.
